(19) United States
(12) Patent Application Publication
(10) Pub. No.: US 2014/0193975 A1
(43) Pub. Date: Jul. 10, 2014

(54) COMPOSITION FOR FORMING TITANIUM-CONTAINING RESIST UNDERLAYER FILM AND PATTERNING PROCESS

(71) Applicant: SHIN-ETSU CHEMICAL CO., LTD., Tokyo (JP)

(72) Inventors: Tsutomu OGIHARA, Jyoetsu (JP); Takafumi UEDA, Jyoetsu (JP); Seiichiro TACHIBANA, Jyoetsu (JP); Yoshinori TANEDA, Jyoetsu (JP)

(73) Assignee: SHIN-ETSU CHEMICAL CO., LTD., Tokyo (JP)

(21) Appl. No.: 14/107,841

(22) Filed: Dec. 16, 2013

(30) Foreign Application Priority Data
Jan. 8, 2013 (JP) 2013-001341

(51) Int. Cl. G03F 7/09; H01L 21/3213

(52) U.S. Cl. CPC G03F 7/092; H01L 21/32139
USPC 438/702; 525/389

(57) ABSTRACT

The invention provides a composition for forming a titanium-containing resist underlayer film comprising: as component (A), a silicon-containing compound obtained by hydrolysis and/or condensation of one or more kinds of silicon compounds shown by the following general formula (A-I) and, as component (B), a titanium-containing compound obtained by hydrolysis and/or condensation of one or more kinds of hydrolysable titanium compounds shown by the following general formula (B-I). There can be provided a composition for forming a titanium-containing resist underlayer film to form a resist underlayer film having an excellent adhesiveness in fine patterning and an excellent etching selectivity relative to a conventional organic film and a silicon-containing film.

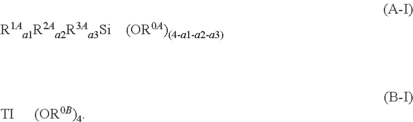

### BACKGROUND OF THE INVENTION

1. Field of the Invention

The present invention relates to a composition for forming a titanium-containing resist underlayer film used in a multilayer resist film used in fine processing in a process for producing a semiconductor device and so on, and a patterning process using the same.

2. Description of the Related Art

In the 1980s, exposure light whose source is g-beam (436 nm) or i-beam (365 nm) of a mercury lamp was commonly used for resist patterning. To achieve a further micro resist pattern, a method for making an exposure wavelength shorter has been regarded as more effective means. In the 1990s, 64 MB (work size: less than 0.25 μM) dynamic random access memory (DRAM) and subsequent electronic devices were mass produced, in which short-wavelength KrF excimer lasers (248 nm) were employed as an exposing source instead of the i-beam (365 nm). In reality, however, the production of DRAMs with an integration degree of 256 MB and more than 1 GB requires finer Processing technology (work size: less than 0.2 μM), and needs a light source of a shorter wavelength. Amid this technological need, the introduction of photolithography by ArF excimer lasers (193 nm) has been seriously examined since about a decade ago. According to initial plan, ARF lithography was introduced in conjunction with the production of 180 nm-node devices, but a conventional KrF excimer lithography was continuously used until 130 nm-node device mass production. Therefore, ARF lithography officially started for the production of 90 nm-node devices. Meanwhile, mass production of 65 nm-node devices, having lenses whose numerical aperture (NA) was raised to 0.9, are being promoted. Because of advantageous shorter exposure wavelength, F₂ lithography with a wavelength of 157 nm was regarded as a next promising production technology for subsequent 45 nm-node devices. However, development of F₂ lithography was canceled due to several problems such as higher scanner costs from expensive CaF₂ single crystals into projection lenses in large volumes, change in the optical system in accordance with introduction of hard pellicles instead of conventional extremely low durable soft pellicles, and reduced etch resistance of a resist film, thereby introducing ArF-immersion lithography.

In ArF-immersion lithography, water with a refractive index of 1.44 is inserted between a projection lens and a wafer by partial fill method, enabling high-speed scanning. Accordingly, 45 nm-node devices are mass produced by using lenses with an NA of 1.3.

Extreme-ultraviolet (EUV) lithography with a wavelength of 13.5 nm is regarded as a next promising 32 nm-node lithography technology. The EUV lithography is prone to numerous technical problems such as needs for higher laser output, higher sensitivity of a resist film, higher resolution, lower line edge roughness (LER), defect-free MoSi laminated mask, and lower aberration of a reflective mirror. Development of another promising 32 nm-node device production technology, or high-refractive index immersion lithography, was canceled due to low transmission factor of another promising high-refractive index lens (LUAG) and an inability to obtain a desired value of a liquid's refractive index at 1.8. As mentioned above, general-purpose light exposure technology seems to fail to significantly improve the resolution so long as a light source wavelength remains the same.

Double patterning process, in which first exposure and development perform patterning and second exposure performs patterning exactly between the patterns obtained by first exposure and development, has recently been focused as a finer processing technology (Non-Patent Document 1). In fact, many processes for a method for double patterning are being proposed. Illustrative example thereof includes a method for forming a photoresist pattern with a rate of line to space in interval of 1:3 by using first exposure and development, processing an underlayer hard mask by dry etching, forming a line pattern at a space portion obtained by exposure and development of the photoresist film after laying another hard mask thereon, processing the hard mask by dry etching, and a line-and-space pattern whose pitch is half that of the first pattern. Also, there is another method for forming a photoresist pattern with a rate of line to space in interval of 1:3 by using first exposure and development, processing an underlayer hard mask by dry etching, exposing a second apace pattern to a remaining portion of the hard mask by applying a photoresist film thereon, and processing the hard mask by dry etching. The former method requires formation of a hard mask twice and the latter method one-time hard mask formation, but it is necessary to form a trench pattern which is difficult to resolve compared to a line pattern. In both methods, a step of processing a hard mask by dry etching is performed twice.

Another finer processing technology is proposed: forming a line pattern on a positive resist film in X direction by using a dipole light, curing a resist pattern, applying a resist composition thereon again, exposing a line pattern in Y direction by using dipole light, and forming a hole pattern from a gap of a lattice line pattern (Non-Patent Document 2).

A method for transferring a lithography pattern on a substrate by using a hard mask is a multilayer resist film. The method is to transfer a pattern on a resist underlayer film by using an upper layer resist pattern as a mask, after interposing e.g. a silicon-containing resist underlayer film as an interlayer film having a different etching selectivity from a photoresist film or a resist upper layer film between the resist upper layer film and a substrate to be processed to obtain a pattern on the resist upper layer film, and transfer a pattern on the substrate to be processed by using the resist underlayer film as an etching mask.

Illustrative example of the composition of a resist underlayer film used in this multilayer resist method includes a CVD silicon-containing inorganic film such as an SiO₂ film (Patent Document 1) and an SiON film (Patent Document 2), and illustrative example of a spin-coating film includes a spin-on glass (SOG) film (Patent Document 3) and a crosslinking silsesquioxane film (Patent Document 4).

Lithography characteristics and stability of a composition for forming a silicon-containing resist underlayer film have been examined. Patent Document 5 discloses a method for providing a resist underlayer film having favorable etching selectivity and storage stability by producing a composition for forming a resist underlayer film containing a thermal crosslinking accelerator. Nevertheless, as finer processing of a semiconductor device further develops, a line width of a pattern becomes narrower. Also, to prevent pattern collapse, film thickness of an upper layer resist film becomes smaller. As to performance required in a resist underlayer film, improvement in adhesiveness and etching selectivity in fine patterning has been increasingly required.

A coating film that is put into practical use in a conventional multilayer resist film is mostly an organic film or the above silicon-containing film. However, in a process for producing a semiconductor device related to a limit domain of lithography by current light exposure, a complicated step such as the above double patterning is proposed. In association therewith, it is increasingly difficult to construct a reasonable process for producing a semiconductor device only using by a conventional organic film and a silicon-containing film. Therefore, in order to construct more reasonable process for producing a semiconductor device, a coating film having an etching selectivity relative to both of these film components is required.

### PRIOR ART REFERENCES

### Patent Documents

Patent Document 1: Japanese Patent Laid-Open Publication No. 7-183194
Patent Document 2: Japanese Patent Laid-Open Publication No. 7-181688
Patent Document 3: Japanese Patent Laid-Open Publication No. 2007-302673
Patent Document 4: Japanese Patent Application Publication No. 2005-520354
Patent Document 5: Japanese Patent No. 4716037
Patent Document 6: Japanese Patent Laid-Open Publication No. 11-258813
Patent Document 7: Japanese Patent Laid-Open Publication No. 2006-251369
Patent Document 8: Japanese Patent Application Publication No. 2005-537502
Patent Document 9: Japanese Patent Laid-Open Publication No. 2005-173552
Patent Document 10: Japanese Patent Laid-Open Publication No. 2006-317864
Patent Document 11: Japanese Patent Laid-Open Publication No. 2000-53921

### Non-Patent Documents

Non-Patent Document 1: PROC. SPIE Vol. 5754 p 1508 (2005)
Non-Patent Document 2: PROC. SPIE Vol. 5377 p 255 (2004)

### SUMMARY OF THE INVENTION

Under the circumstances, resist underlayer films composed of various kinds of metal compound are proposed, some of which include a titanium-containing coating film as a coating film possibly having the above etching selectivity (Patent Documents 6 to 10). Patent Document 6 shows KrF exposure patterning evaluation by using polytitanoxane, but patterning evaluation by ArF exposure which is currently and widely applied is not carried out therein. Patent Document 7 shows patterning evaluation by i-beam exposure by using a hydrolysate of each metal alkoxide, but exhibits no patterning evaluation by ArF exposure which is currently and widely applied as well as Document 6. Patent Document 8 describes no patterning evaluation, thus the actual pattern adhesiveness performance is not known. Meanwhile, Patent Documents 9 and 10 describe use of a mixture of a titanium-containing compound and a silicon-containing compound or hydrolysis product, and ArF exposure evaluation is performed and consequently the pattern adhesiveness is confirmed. Nevertheless, using a combination of a silicon-containing compound and a titanium-containing compound in the document, it is difficult to rule out an impact of a silicon-containing compound on a dry etching selectivity, and an etching selectivity derived from a film formed by the titanium-containing compound is not expected.

On the other hand, there is a method for forming a 2-layer structure by mixing substances of different properties and coating them as a film. Patent Document 11 describes a method for forming a 2-layer anti-reflection film to reduce reflection of a visible light. Specifically, this method is characterized by introduction of a composition for forming an anti-reflection coating containing a compound that can provide a cured film having a low refractive index containing a fluorine atom and a compound that can give a cured film having a high refractive index whose surface free energy is higher than the a cured film having a low refractive index containing a fluorine atom. The method forms a 2-layer structure by one-time coating to reduce the reflectance and maintain productivity at the same time. However, if a difference in polymer free energy is not appropriate, a sea-island structure in which a matrix of one phase has a domain of the other phase is often found, and it is necessary to find out an appropriate combination of compounds that can form a 2-layer structure by using titanium dioxide.

The present invention was made in view of the above situation, and has an object to provide a composition for forming a titanium-containing resist underlayer film for forming a resist underlayer film having an excellent adhesiveness in fine patterning and an excellent etching selectivity with a conventional organic film and a silicon-containing film.

The present invention provides a composition for forming a titanium-containing resist underlayer film comprising:

as a component (A), a silicon-containing compound obtained by hydrolysis and/or condensation of one or more kinds of silicon compounds shown by the following general formula (A-I),

R^{1A}ₐ₁R^{2A}ₐ₂R^{3A}ₐ₃Si(OR^{0A})₍₄₋ₐ₁₋ₐ₂₋ₐ₃₎ (A-I)

wherein, R^{OA} represents a hydrocarbon group having 1 to 6 carbon atoms; R^{1A}, R^{2A} and R^{3A} represent a hydrogen atom or a monovalent organic group having 1 to 30 carbon atoms; and a1, a2 and a3 represent 0 or 1 and satisfy 1≦A1+A2+A3≦3, and

as a component (B), a titanium-containing compound obtained by hydrolysis and/or condensation of one or more kinds of a hydrolysable titanium compound represented by the following general formula (B-I),

Ti(OR^{0B})₄ (B-I)

wherein, R^{0B} represents an organic group having 1 to 10 carbon atoms.

A composition for forming a resist underlayer film containing a hydrolytic condensate of the silicon compound represented by the above (A-I) and a hydrolytic condensate of the titanium compound represented by (B-I) can form a 2-layer structure without forming a sea-island structure.

The composition for forming a titanium-containing resist underlayer film can form a resist underlayer film having an excellent adhesiveness in fine patterning and an excellent etching selectivity with a conventional organic film and a silicon-containing film.

In this case, the component (A) preferably contains a silicon-containing compound obtained by hydrolysis and/or condensation of one or more kinds of silicon compounds shown by the general formula (A-I) and one or more kinds of hydrolysable metal compounds shown by the following general formula (A-II),

L(OR^{4A})ₐ₄(OR^{5A})ₐ₅(O)ₐ₆ (A-II)

wherein, R^{4A} and R^{SA} represent an organic group having 1 to 30 carbon atoms; a4, a5 and a6 represent an integer of 0 or more and a4+a5+2×a6 is the same number as the number determined by valency of L; and L is an element belonging to groups of III, IV, or V in a periodic table except for carbon.

L of the general formula (A-II) is preferably any of boron, silicon, aluminum, gallium, yttrium, germanium, titanium, zirconium, hafnium, bismuth, tin, phosphorous, vanadium, arsenic, antimony, niobium, and tantalum.

A composition for forming a titanium-containing resist underlayer film containing a component (A-II) as the component (A) can further improve the etching selectivity when a resist underlayer film is formed.

Any one or more of R^{1A}, R^{2A} and R^{3A} in the general formula (A-I) is an organic group containing a hydroxyl group or a carboxyl group, the groups being substituted with an acid-labile group.

A composition for forming titanium-containing resist underlayer film containing component (A) further improves the pattern adhesiveness when a resist underlayer film is formed.

The present invention provides a patterning process to form a pattern on a body to be processed, wherein an organic underlayer film is formed on a body to be processed by using an application-type composition for the organic underlayer film, on the organic underlayer film is formed a titanium-containing resist underlayer film by using the composition for forming the titanium-containing resist underlayer film, on the titanium-containing resist underlayer film is formed a photoresist film by using a chemically amplified resist composition, the photoresist film is exposed to a high energy beam after heat treatment, a positive pattern is formed by dissolving an exposed area of the photoresist film by using an alkaline developer, pattern transfer is made onto the titanium-containing resist underlayer film by using the photoresist film having the positive pattern as a mask, pattern transfer is made onto the organic underlayer film by using the titanium-containing resist underlayer film having the transferred pattern as a mask, and then pattern transfer is made onto the body to be processed by using the organic underlayer film having the transferred pattern as a mask.

The present invention provides a patterning process to form a pattern on a body to be processed, wherein an organic hard mask mainly comprising carbon is formed on a body to be processed by a CVD method, on the organic hard mask is formed a titanium-containing resist underlayer film by using the composition for forming the titanium-containing resist underlayer film, on the titanium-containing resist underlayer film is formed a photoresist film by using a chemically amplified resist composition, the photoresist film is exposed to a high energy beam after heat treatment, a positive pattern is formed by dissolving an exposed area of the photoresist film by using an alkaline developer, pattern transfer is made onto the titanium-containing resist underlayer film by using the photoresist film having the positive pattern as a mask, pattern transfer is made onto the organic hard mask by using the titanium-containing resist underlayer film having the transferred pattern as a mask, and then pattern transfer is made onto the body to be processed by using the organic hard mask having the transferred pattern as a mask.

By forming a positive pattern by using a composition for forming a titanium-containing resist underlayer film of the present invention, optimization of a combination of an organic underlayer film or an organic hard mask as described above can form a pattern that is formed by a photoresist on a body to be processed without a size conversion difference.

The present invention is a patterning process to form a pattern on a body to be processed, wherein an organic underlayer film is formed on a body to be processed by using an application-type composition for the organic underlayer film, on the organic underlayer film is formed a titanium-containing resist underlayer film by using the composition for forming the titanium-containing resist underlayer film, on the titanium-containing resist underlayer film is formed a photoresist film by using a chemically amplified resist composition, the photoresist film is exposed to a high energy beam after heat treatment, a negative pattern is formed by dissolving an unexposed area of the photoresist film by using an organic solvent developer, pattern transfer is made onto the titanium-containing resist underlayer film by using the photoresist film having the negative pattern as a mask, pattern transfer is made onto the organic underlayer film by using the titanium-containing resist underlayer film having the transferred pattern as a mask, and then pattern transfer is made onto the body to be processed by using the organic underlayer film having the transferred pattern as a mask.

The present invention provides a patterning process to form a pattern on a body to be processed, wherein an organic hard mask mainly comprising carbon is formed on a body to be processed by a CVD method, on the organic hard mask is formed a titanium-containing resist underlayer film by using the composition for forming the titanium-containing resist underlayer film, on the titanium-containing resist underlayer film is formed a photoresist film by using a chemically amplified resist composition, the photoresist film is exposed to a high energy beam after heat treatment, a negative pattern is formed by dissolving an unexposed area of the photoresist film by using an organic solvent developer, pattern transfer is made onto the titanium-containing resist underlayer film by using the photoresist film having the negative pattern as a mask, pattern transfer is made onto the organic hard mask by using the titanium-containing resist underlayer film having the transferred pattern as a mask, and then pattern transfer is made onto the body to be processed by using the organic hard mask having the transferred pattern as a mask.

By forming a negative pattern by using a composition for forming a titanium-containing resist underlayer film of the present invention, optimization of a combination of an organic underlayer film and an organic hard mask as described above can form a pattern that is formed by a photoresist on a body to be processed without a size conversion difference.

In this case, the body to be processed is preferably a semiconductor substrate coated, as a layer to be processed, with any of a metal film, a metal carbide film, a metal oxide film, a metal nitride film, a metal oxycarbide film, and a metal oxynitride film.

Moreover, the metal that constitutes the body to be processed is preferably silicon, titanium, tungsten, hafnium, zirconium, chromium, germanium, copper, aluminum, indium, gallium, arsenic, palladium, iron, tantalum, iridium, molybdenum or an alloy of these metals.

In this manner, the patterning process of the present invention can form a pattern by processing the body to be processed as described above.

In the patterning process on the photoresist film, the photoresist film is preferably exposed by any of the method of photolithography with a wavelength of 300 nm or less or an EUV beam, and the method of a direct drawing with an electron beam.

By using one of these methods, fine pattern can be formed on a photoresist film.

The composition for forming a titanium-containing resist underlayer film of the present invention can form a 2-layer structure without forming a sea-island structure when a resist underlayer film is formed. By patterning by using a titanium-containing resist underlayer film formed by using the composition for forming a titanium-containing resist underlayer film, an upper layer portion with silicon formed in an upper portion as a main component exhibits favorable adhesiveness relative to a photoresist pattern, and a high etching selectivity relative to a photoresist pattern and an organic underlayer film or an organic hard mask formed in a lower portion, a fine photoresist pattern can be transferred on an organic underlayer film or an organic hard mask without a size conversion difference, and a body to be processed can be processed with a high precision.

### DETAILED DESCRIPTION OF THE PREFERRED EMBODIMENTS

Inventors of the present invention have carried out extended research on lithography characteristics and stability of a composition for forming a silicon-containing resist underlayer film to produce a resist underlayer film having an etching selectivity and storage stability by using a silicon-containing compound. However, a finer processing of a semiconductor device is being developed than before, and a complicated step such as double patterning is proposed to require further improvement in a resist underlayer film composition. Accordingly, inventors of the present invention found out that by using a coating film containing a titanium dioxide having a higher etching resistance than a silicon dioxide as a resist underlayer film, a complicated finer processing step such as recent double patterning can be generated. Moreover, they found a possibility that in order to improve the adhesiveness with a resist pattern, a composition in which a silicon-containing compound is added to a titanium-containing resist underlayer film improve the adhesiveness with an upper layer resist pattern and provides a resist underlayer film without a pattern collapse.

By spin-coating a composition containing the above-described silicon-containing compound and the titanium-containing compound, the silicon-containing compound is partially provided with a 2-layer structure on a coating film surface. This is attributable to formation of a 2-layer structure from phase separation that caused by growth of molecule's alignment and aggregate in itself to perform the free energy of a film surface becoming a minimum level when a film is formed. The method forms a 2-layer structure by one-time coating to reduce the reflectance and maintain productivity at the same time. However, if a difference in polymer free energy is not appropriate, a 2-layer structure is not always formed by phase separation, and a sea-island structure in which a matrix of one phase has a domain of the other phase is often found, it is necessary to find out favorable combination of compositions to form a 2-layer structure.

It is widely known that a surfactant having a perfluoroalkyl group and a siloxane comes up to a resist film surface after spin-coating to cover a surface. This stabilization is found by orienting a perfluoroalkyl group and a siloxane having a low surface free energy to the surface. According to Japanese Patent Laid-Open Publication No. 2007-297590, when a polymer having a —C (CF₃)₂OH structure is added to a photoresist film in operation, it is oriented to a film surface.

Inventors of the present invention found out that by adding an appropriate siloxane compound having a low surface free energy to a composition for forming a titanium-containing resist underlayer film, a 2-layer structure with a component whose resist underlayer film surface partially is improved in adhesiveness with an upper layer resist pattern can be formed without forming a sea-island structure to complete the present invention.

The present invention provides a composition for forming a titanium-containing resist underlayer film comprising:

as component (A), a silicon-containing compound obtained by hydrolysis and/or condensation of one or more kinds of silicon compounds shown by the following general formula (A-I),

R^{1A}ₐ₁R^{2A}ₐ₂R^{3A}ₐ₃Si(OR^{0A})₍₄₋ₐ₁₋ₐ₂₋ₐ₃₎ (A-I)

wherein, R^{OA} represents a hydrocarbon group having 1 to 6 carbon atoms, R^{1A}, R^{2A} and R^{3A} represent a hydrogen atom or a monovalent organic group having 1 to 30 carbon atoms. a1, a2 and a3 represent 0 or 1 and satisfy 1≦A1+A2+A3≦3, and

as a component (B), a titanium-containing compound obtained by hydrolysis and/or condensation of one or more kinds of a hydrolysable titanium compound shown by the following general formula (B-I),

Ti(OR^{0B})₄ (B-I)

wherein, R^{0B} represents an organic group having 1 to 10 carbon atoms.

Each component will be described in detail.

### Component (A)

The silicon-containing compound as the component (A) of the composition for forming a titanium-containing resist underlayer film of the present invention can employ one or more kinds of silicon compounds shown by the following general formula (A−1) as a raw material.

R^{1A}ₐ₁R^{2A}ₐ₂R^{3A}ₐ₃Si(OR^{0A})₍₄₋ₐ₁₋ₐ₂₋ₐ₃₎ (A-I)

wherein, R^{OA} represents a hydrocarbon group having 1 to 6 carbon atoms, R^{1A}, R^{2A} and R^{3A} represent a hydrogen atom or a monovalent organic group having 1 to 30 carbon atoms; and a1, a2 and a3 represent 0 or 1 and satisfy 1≦A1+A2+A3≦3.

Illustrative example of the silicon compound represented by the above general formula (A-I) includes trimethoxysilane, triethoxysilane, tripropoxysilane, triisopropoxysilane, methyltrimethoxysilane, methyltriethoxysilane, methyltripropoxysilane, methyltriisopropoxysilane, ethyltrimethoxysilane, ethyltriethoxysilane, ethyltripropoxysilane, ethyltriisopropoxysilane, vinyltrimethoxysilane, vinyltriethoxysilane, vinyltripropoxysilane, vinyltriisopropoxysilane, propyltrimethoxysilane, propyltriethoxysilane, propyltripropoxysilane, propyltriisopropoxysilane, isopropyltrimethoxysilane, isopropyltriethoxysilane, isopropyltripropoxysilane, isopropyltriisopropoxysilane, butyltrimethoxysilane, butyltriethoxysilane, butyltripropoxysilane, butyltriisopropoxysilane, sec-butyltrimethoxysilane, sec-butyltriethoxysilane, sec-butyltripropoxysilane, sec-butyltriisopropoxysilane, t-butyltrimethoxysilane, t-butyltriethoxysilane, t-butyltripropoxysilane, t-butyltriisopropoxysilane, cyclopropyltrimethoxysilane, cyclopropyltriethoxysilane, cyclopropyltripropoxysilane, cyclopropyltriisopropoxysilane, cyclobutyltrimethoxysilane, cyclobutyltriethoxysilane, cyclobutyltripropoxysilane, cyclobutyltriisopropoxysilane, cyclopentyltrimethoxysilane, cyclopentyltriethoxysilane, cyclopentyltripropoxysilane, cyclopentyltriisopropoxysilane, cyclohexyltrimethoxysilane, cyclohexyltriethoxysilane, cyclohexyltripropoxysilane, cyclohexyltriisopropoxysilane, cyclohexenyltrimethoxysilane, cyclohexenyltriethoxysilane, cyclohexenyltripropoxysilane, cyclohexenyltriisopropoxysilane, cyclohexenylethyltrimethoxysilane, cyclohexenylethyltriethoxysilane, cyclohexenylethyltripropoxysilane, cyclohexenylethyltriisopropoxysilane, cyclooctyltrimethoxysilane, cyclooctyltriethoxysilane, a cyclooctyltripropoxysilane, cyclooctyltriisopropoxysilane, cyclopentadienylpropyltrimethoxysilane, cyclopentadienylpropyltriethoxysilane, cyclopentadienylpropyltripropoxysilane, cyclopentadienylpropyltriisopropoxysilane, bicycloheptenyltrimethoxysilane, bicycloheptenyltriethoxysilane, bicycloheptenyltripropoxysilane, bicycloheptenyltriisopropoxysilane, bicycloheptyltrimethoxysilane, bicycloheptyltriethoxysilane, bicycloheptyltripropoxysilane, bicycloheptyltriisopropoxysilane, adamanthyltrimethoxysilane, adamanthyltriethoxysilane, adamanthyltripropoxysilane, adamanthyltriisopropoxysiiane, phenyltrimethoxysilane, phenyltriethoxysilane, phenyltripropoxysilane, phenyltriisopropoxysilane, benzyltrimethoxysilane, benzyltriethoxysilane, benzyltripropoxysilane, benzyltriisopropoxysilane, tolyltrimethoxysilane, tolyltriethoxysilane, tolyltripropoxysilane, tolyltriisopropoxysilane, anisyltrimethoxysilane, anisyltriethoxysilane, anisyltripropoxysilane, anisyltriisopropoxysilane, phenethyltrimethoxysilane, phenethyltriethoxysilane, phenethyltripropoxysilane, phenethyltriisopropoxysilane, naphthyltrimethoxysilane, naphthyltriethoxysilane, naphthyltripropoxysilane, naphthyltriisopropoxysilane, dimethyldimethoxysilane, dimethyldiethoxysilane, methylethyldimethoxysilane, methylethyldiethoxysilane, dimethyldipropoxysilane, dimethyldiisopropoxysilane, diethyldimethoxysilane, diethyldiethoxysilane, diethyldipropoxysilane, diethyldiisopropoxysilane, dipropyldimethoxysilane, dipropyldiethoxysilane, dipropyldipropoxysilane, dipropyldiisopropoxysilane, diisopropyldimethoxysilane, diisopropyldiethoxysilane, diisopropyldipropoxysilane, diisopropyldiisopropoxysilane, dibutyldimethoxysilane, dibutyldiethoxysilane, dibutyldipropoxysilane, dibutyldiisopropoxysilane, di-sec-butyldimethoxysilane, di-sec-butyldiethoxysilane, di-sec-butyldipropoxysilane, di-sec-butyldiisopropoxysilane, di-t-butyldimethoxysilane, di-t-butyldiethoxysilane, di-t-butyldipropoxysilane, di-t-butyldilsopropoxysilane, dicyclopropyldimethoxysilane, dicyclopropyldiethoxysilane, dicyclopropyldipropoxysilane, dicyclopropyldiisopropoxysilane, dicyclobutyldimethoxysilane, dicyclobutyldiethoxysilane, dicyclobutyldipropoxysilane, dicyclobutyldiisopropoxysilane, dicyclopentyldimethoxysilane, dicyclopentyldiethoxysilane, dicyclopentyldipropoxysilane, dicyclopentyldiisopropoxysilane, dicyclohexyldimethoxysilane, dicyclohexyldiethoxysilane, dicyclohexyldipropoxysilane, dicyclohexyldiisopropoxysilane, dicyclohexenyldimethoxysilane, dicyclohexenyldiethoxysilane, dicyclohexenyldipropoxysilane, dicyclohexenyldilsopropoxysilane, dicyclohexenylethyldimethoxysilane, dicyclohexenylethyldiethoxysilane, dicyclohexenylethyldipropoxysilane, dicyclohexenylethyldiisopropoxysilane, dicyclooctyldimethoxysilane, dicyclooctyldiethoxysilane, dicyclooctyldipropoxysilane, dicyclooctyldiisopropoxysilane, dicyclopentadienylpropyldimethoxysilane, dicyclopentadienylpropyldiethoxysilane, dicyclopentadienylpropyldipropoxysilane, dicyclopentadienylpropyldiisopropoxysilane, bis(bicycloheptenyl)dimethoxysilane, bis(bicycloheptenyl) diethoxysilane, bis(bicycloheptenyl)dipropoxysilane, bis(bicycloheptenyl)diisopropoxysilane, bis(bicycloheptyl)dimethoxysilane, bis(bicycloheptyl) diethoxysilane, bis(bicycloheptyl)dipropoxysilane, bis(bicycloheptyl)diisopropoxysilane, diadamanthyldimethoxysilane, diadamanthyldiethoxysilane, diadamanthyldipropoxysilane, diadamanthyldiisopropoxysilane, diphenyldimethoxysilane, diphenyldiethoxysilane, methylphenyldimethoxysilane, methylphenyldiethoxysilane, diphenyldipropoxysilane, diphenyldiisopropoxysilane, trimethylmethoxysilane, trimethylethoxysilane, dimethylethylmethoxysilane, dimethylethylethoxysilane, dimethylphenylmethoxysilane, dimethylphenylethoxysilane, dimethylbenzylmethoxysilane, dimethylbenzylethoxysilane, dimethylphenethylmethoxysilane, and dimethylphenethylethoxysilane.

One or more of R^{1A}, R^{2A} and R^{3A} in the above general formula (A-I) may be an organic group containing a hydroxyl group or a carboxyl group, the groups being substituted with an acid-labile group, and illustrative example of the organic group of the silicon compound includes the one having 2 or 3 methoxy groups, ethoxy groups, propoxy groups, butoxy groups, pentoxy groups, cyclopentoxy groups, hexyloxy groups, cyclohexyloxy groups and phenoxy groups as shown below.

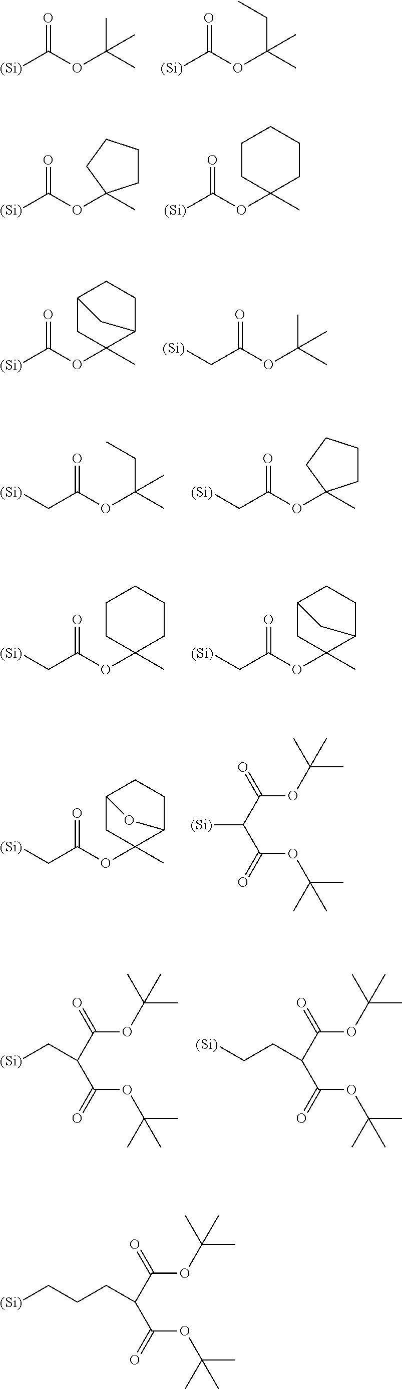

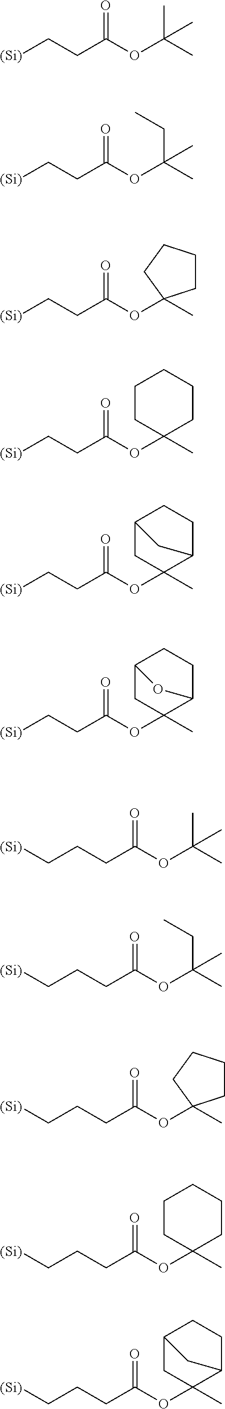

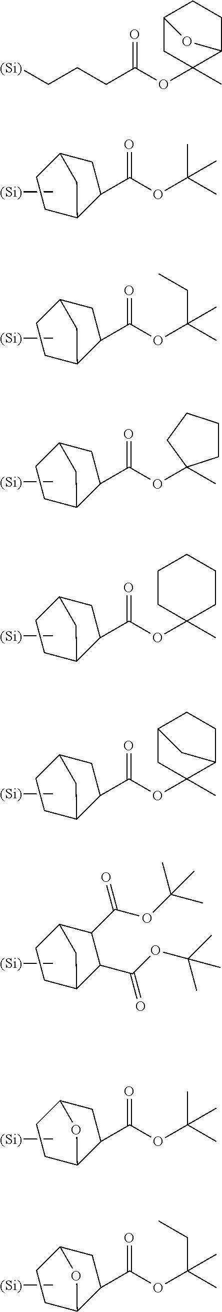

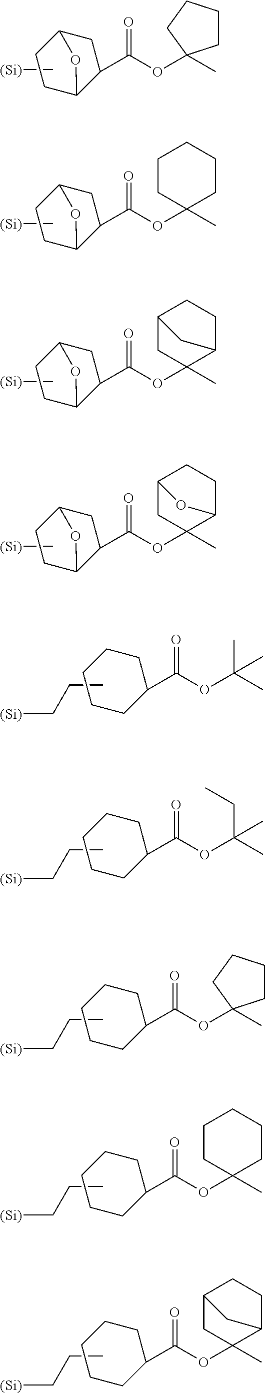

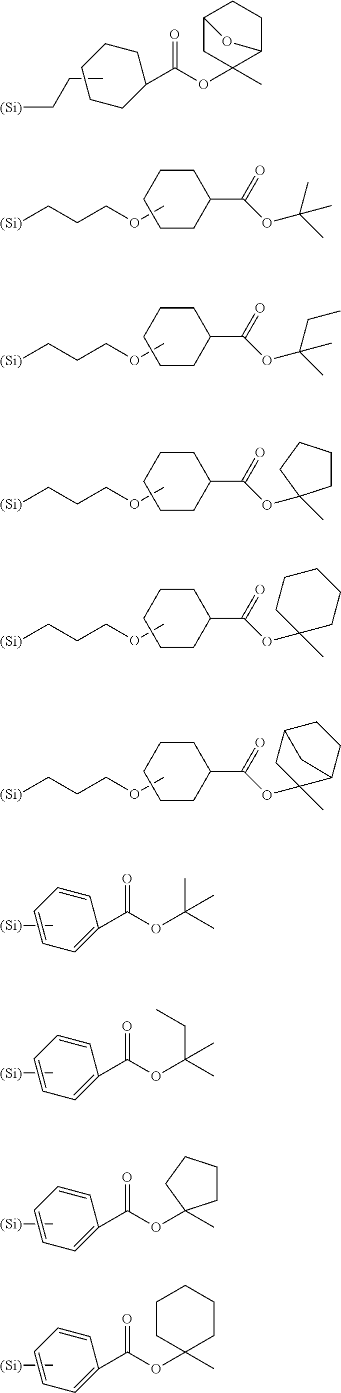

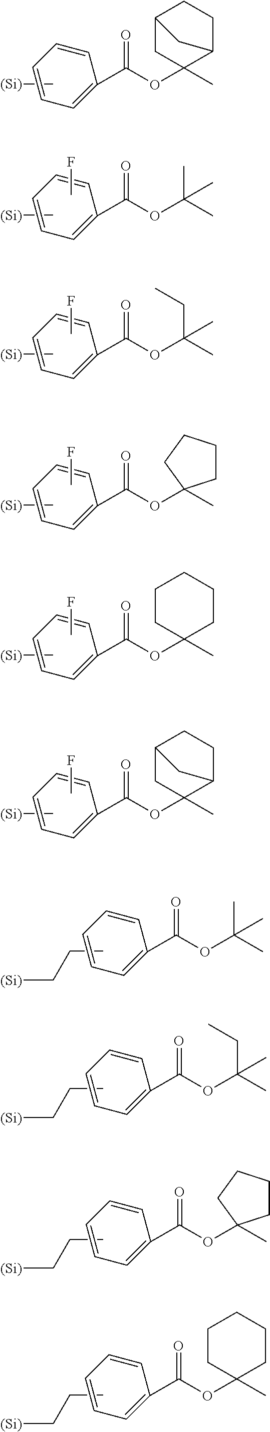

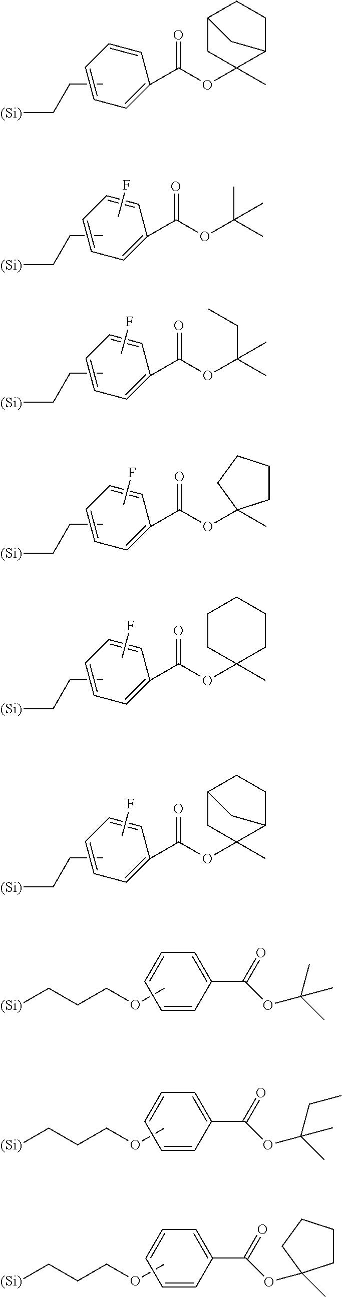

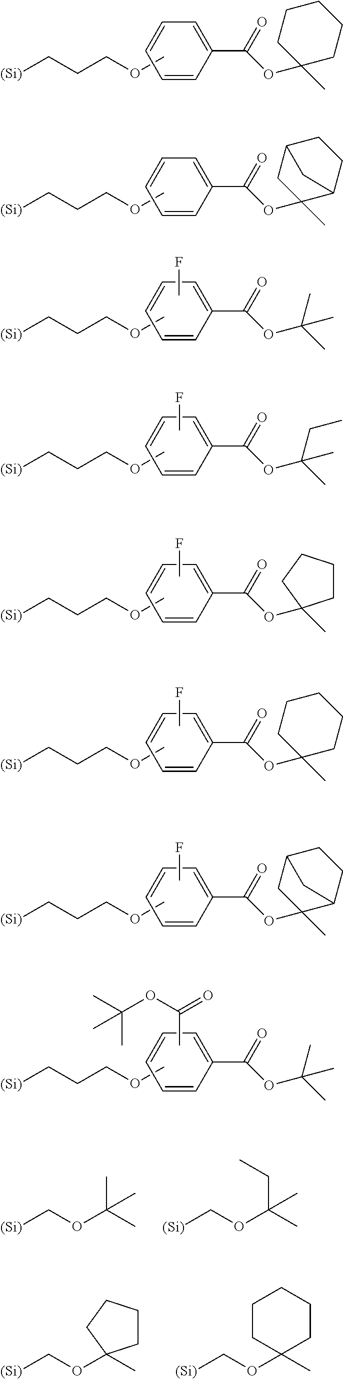

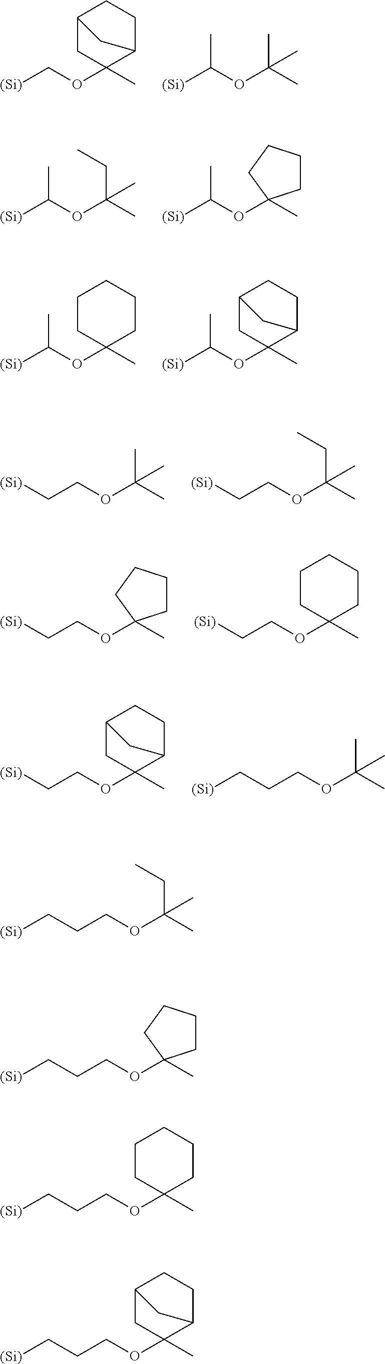

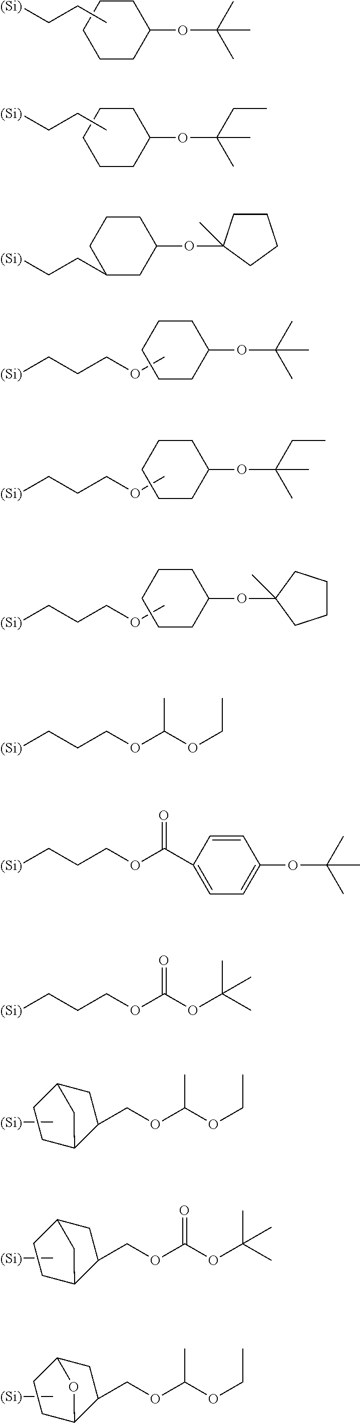

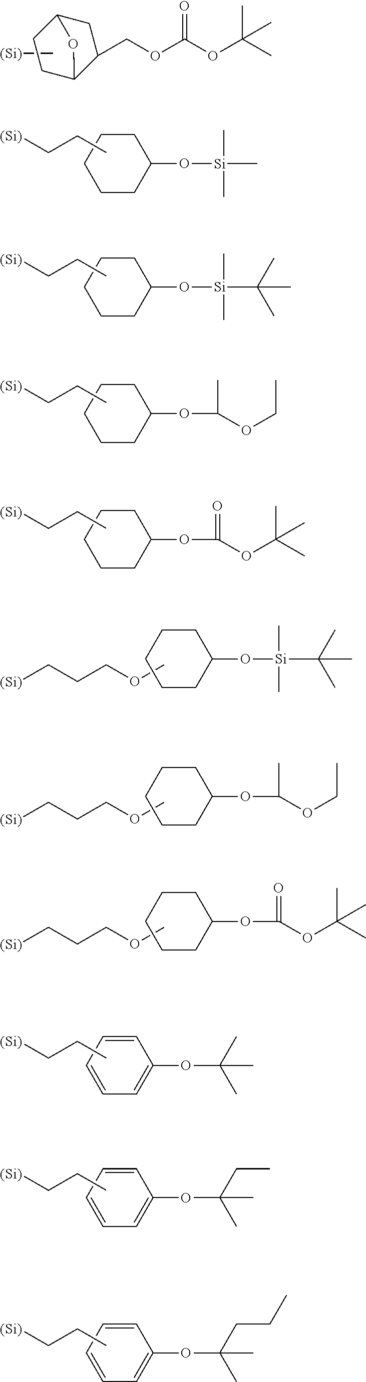

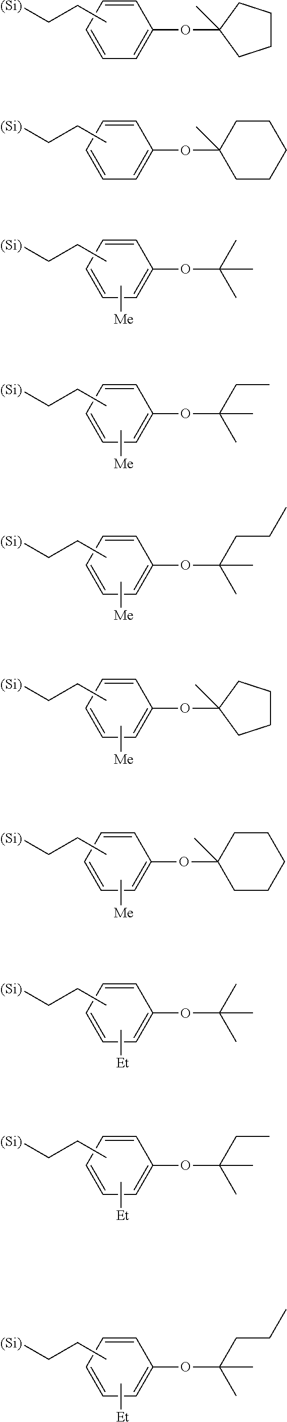

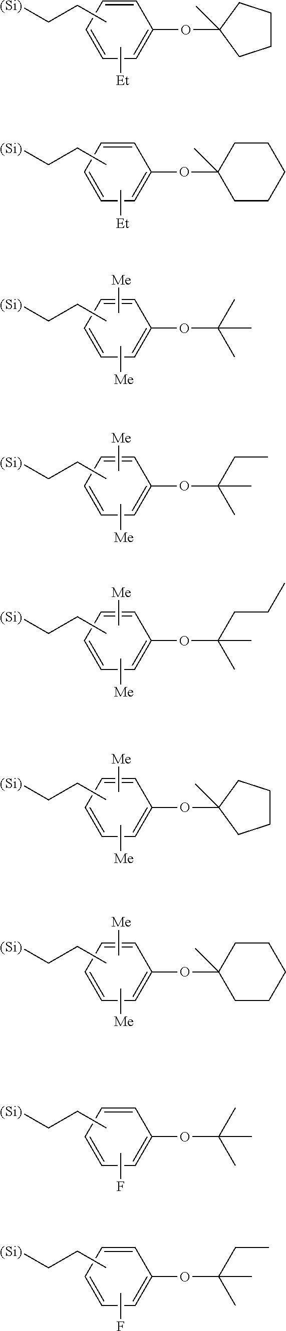

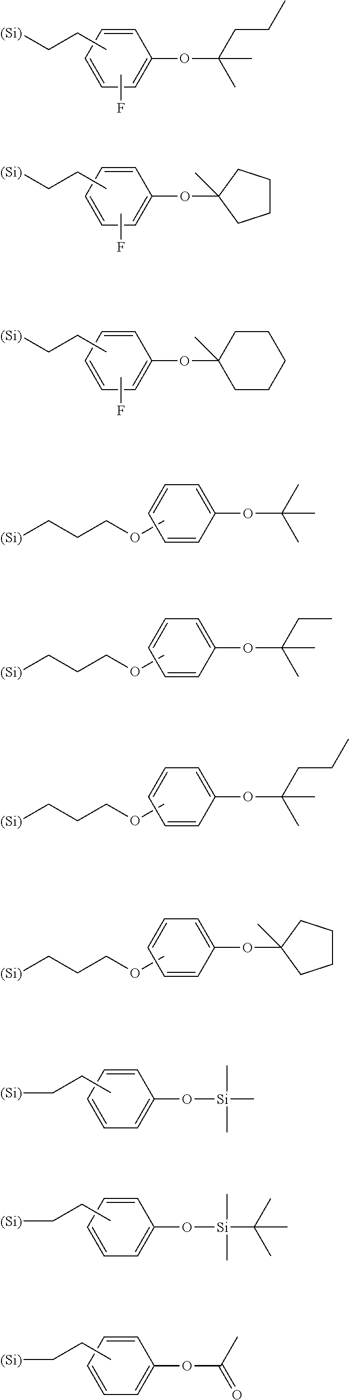

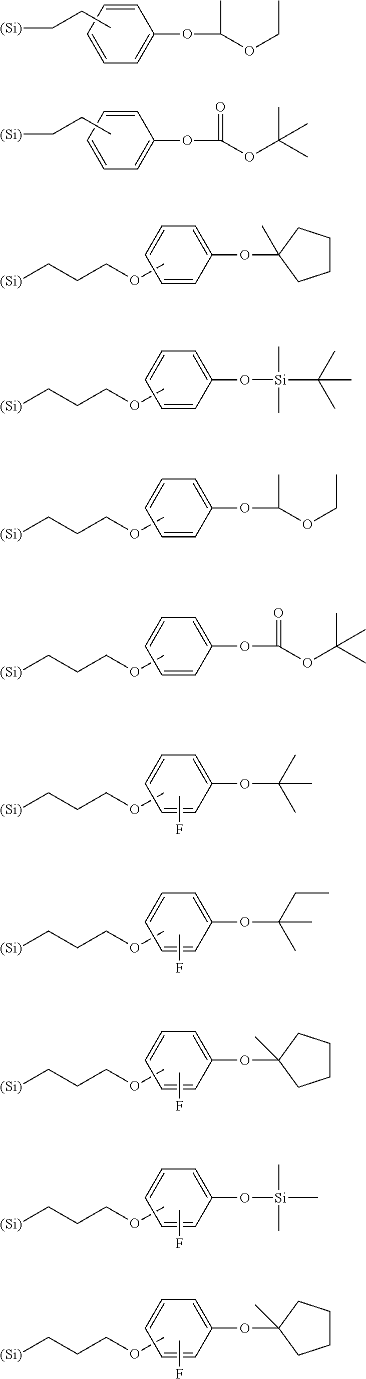

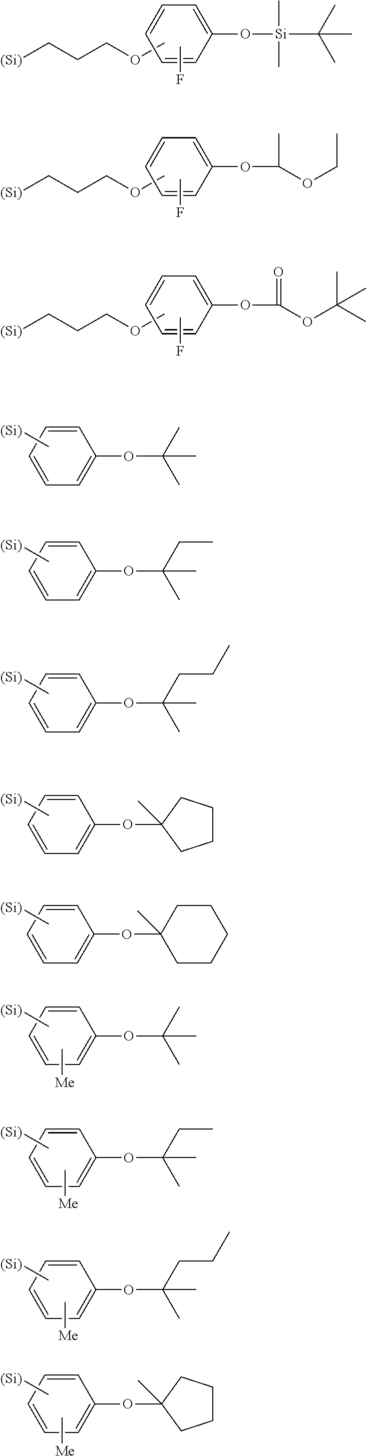

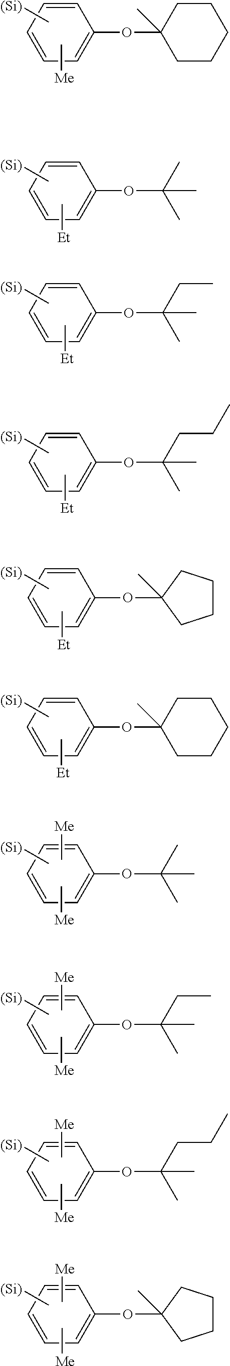

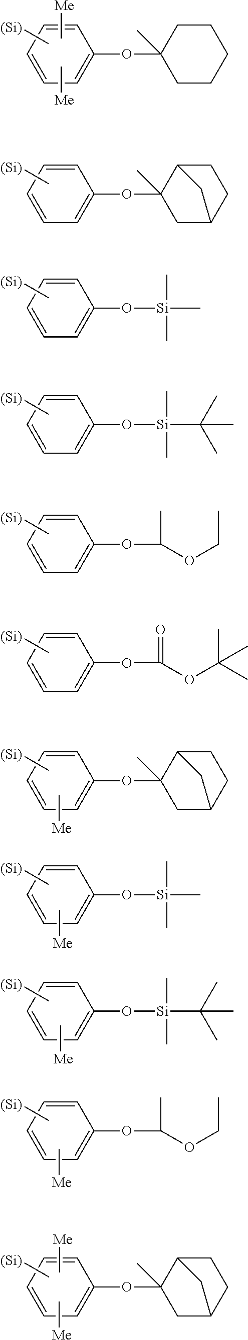

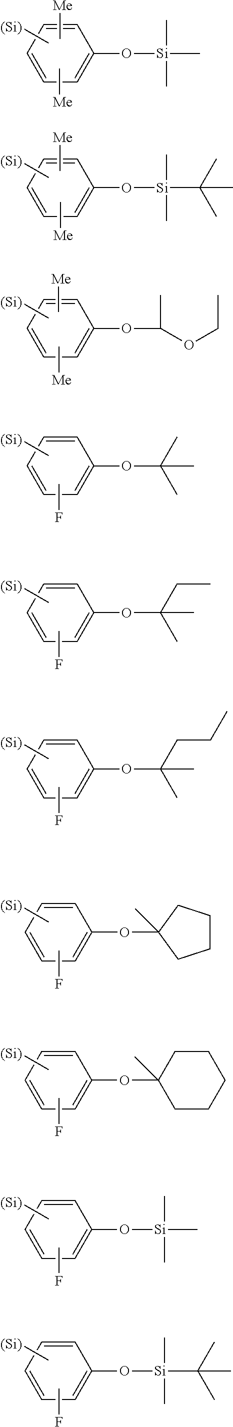

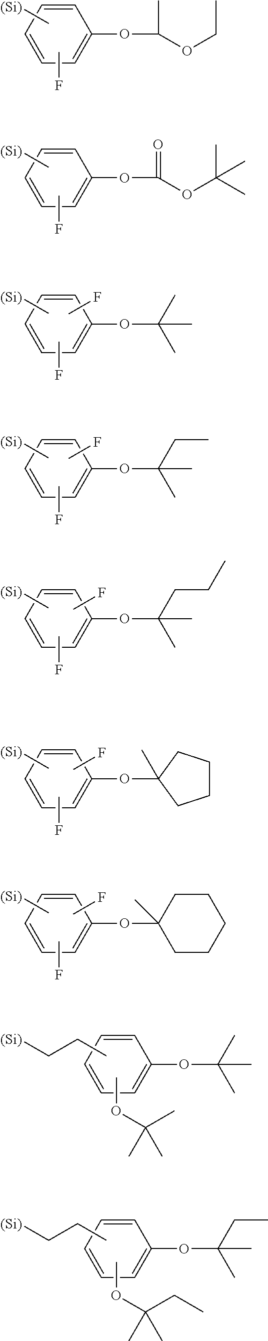

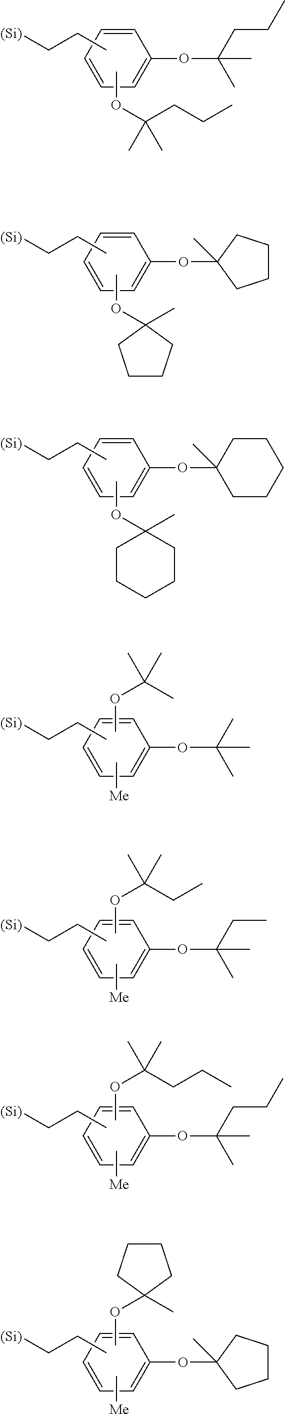

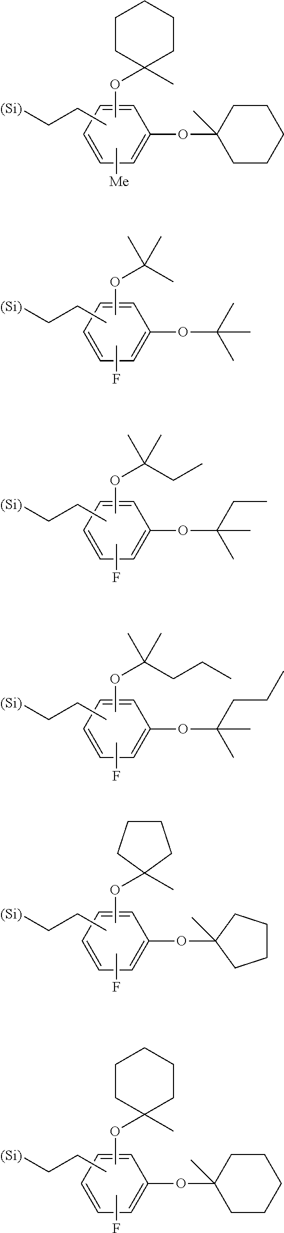

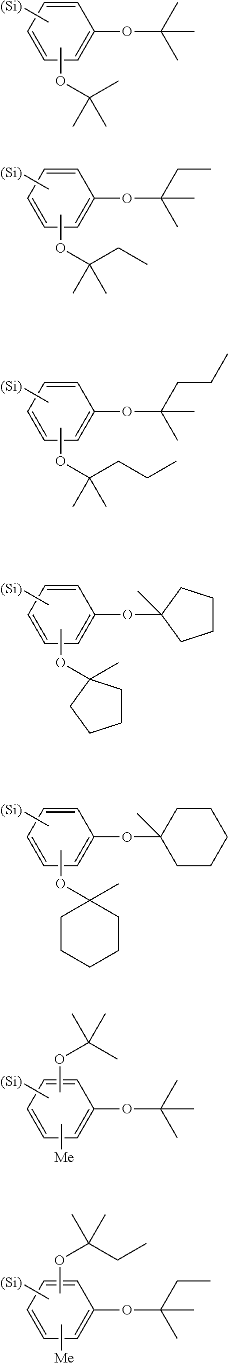

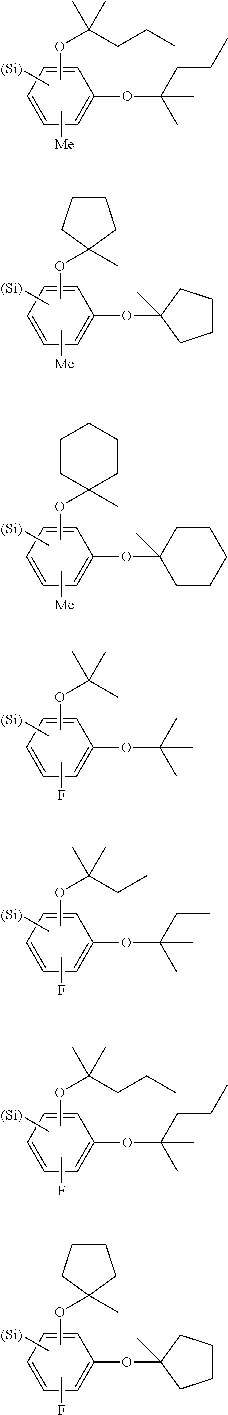

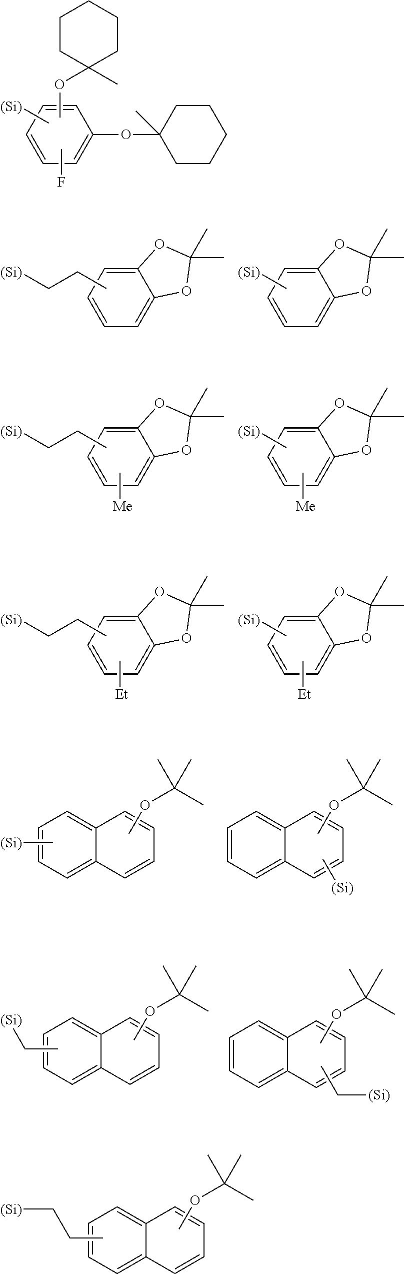

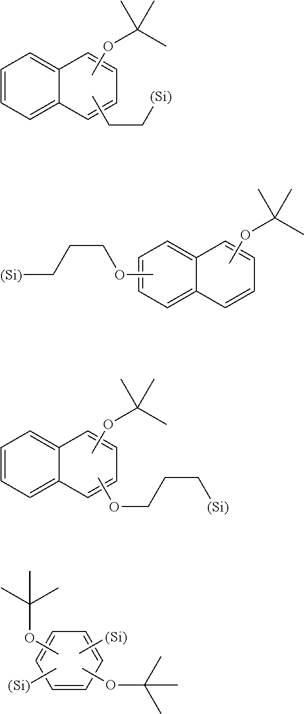

As the component (A), one or more kinds of hydrolysable metal compounds shown by the following general formula (A-II) can be used as other raw materials,

L(OR^{4A})ₐ₄(OR^{5A})ₐ₅(O)ₐ₆ (A-II)

wherein, R^{4A} and R^{5A} represent an organic group having 1 to 30 carbon atoms; a4, a5 and a6 represent an integer of 0 or more and a4+a5+2×a6 is the same number as the number determined by valency of L; and L is an element belonging to groups of III, IV, or V in a periodic table except for carbon.

Preferably, the L in the above general formula (A-II) is any element of boron, silicon, aluminum, gallium, yttrium, germanium, titanium, zirconium, hafnium, bismuth, tin, phosphorous, vanadium, arsenic, antimony, niobium or tantalum. Such a metal compound can be illustrated as follows.

If L is boron, illustrative example of the hydrolysable metal compound includes boron methoxide, boron ethoxide, boron propoxide, boron butoxide, boron amyloxide, boron hexyloxide, boron cyclopentoxide, boron cyclohexyloxide, boron allyloxide, boron phenoxide, boron methoxyethoxide, boric acid, and boron oxide as a monomer.

If L is silicon, illustrative example of the hydrolysable metal compound includes tetramethoxysilane, tetraethoxysilane, tetrapropoxysilane, tetraisopropoxysilane, tetrabutoxysilane, tetraphenoxysilane, and tetraacetoxysilane as a monomer.

If L is aluminum, illustrative example of the hydrolysable metal compound includes aluminum methoxide, aluminium ethoxide, aluminum propoxide, aluminum butoxide, aluminum amyloxide, aluminum hexyloxide, aluminum cyclopentoxide, aluminum cyclohexyloxide, aluminum allyloxide, aluminum phenoxide, aluminum methoxyethoxide, aluminum ethoxyethoxide, aluminum dipropoxyethyl acetoacetate, aluminum dibutoxyethyl acetoacetate, aluminum propoxy bisethyl acetoacetate, aluminum butoxy bisethyl acetoacetate, aluminum 2,4-pentanedionate, and aluminum 2,2,6,6-tetramethyl-3,5-heptanedionate as a monomer.

If L is gallium, illustrative example of the hydrolysable metal compound includes gallium methoxide, gallium ethoxide, gallium propoxide, gallium butoxide, gallium amyloxide, gallium hexyloxide, gallium cyclopentoxide, gallium cyclohexyloxide, gallium allyloxide, gallium phenoxide, gallium methoxyethoxide, gallium ethoxyethoxide, gallium dipropoxyethyl acetoacetate, gallium dibutoxyethyl acetoacetate, gallium propoxy bisethyl acetoacetate, gallium butoxy bisethyl acetoacetate, gallium 2,4-pentanedionate, and gallium 2,2,6,6-tetramethyl-3,5-heptanedionate as a monomer.

If L is yttrium, illustrative example of the hydrolysable metal compound includes yttrium methoxide, yttrium ethoxide, yttrium propoxide, yttrium butoxide, yttrium amyloxide, yttrium hexyloxide, yttrium cyclopentoxide, yttrium cyclohexyloxide, yttrium allyloxide, yttrium phenoxide, yttrium methoxyethoxide, yttrium ethoxyethoxide, yttrium dipropoxyethyl acetoacetate, yttrium dibutoxyethyl acetoacetate, yttrium propoxy bisethyl acetoacetate, yttrium butoxy bisethyl acetoacetate, yttrium 2,4-pentanedionate, and yttrium 2,2,6,6-tetramethyl-3,5-heptanedionate as a monomer.

If L is germanium, illustrative example of the hydrolysable metal compound includes germanium methoxide, germanium ethoxide, germanium propoxide, germanium butoxide, germanium amyloxide, germanium hexyloxide, germanium cyclopentoxide, germanium cyclohexyloxide, germanium allyloxide, germanium phenoxide, germanium methoxyethoxide, and germanium ethoxyethoxide as a monomer.

If L is titanium, illustrative example of the hydrolysable metal compound includes titanium methoxide, titanium ethoxide, titanium propoxide, titanium butoxide, titanium amyloxide, titanium hexyloxide, titanium cyclopentoxide, titanium cyclohexyloxide, titanium allyloxide, titanium phenoxide, titanium methoxyethoxide, titanium ethoxyethoxide, titanium dipropoxy bisethyl acetoacetate, titanium dibutoxy bisethyl acetoacetate, titanium dipropoxy bis 2,4-pentanedionate, and titanium dibutoxy bis 2,4-pentanedionate as a monomer.

If L is zirconium, illustrative example of the hydrolysable metal compound includes methoxy zirconium, ethoxy zirconium, propoxy zirconium, butoxy zirconium, phenoxy zirconium, zirconium dibutoxidebis(2,4-pentanedionate), and zirconium dipropoxidebis(2,2,6,6-tetramethyl-3,5-heptanedionate) as a monomer.

If L is hafnium, illustrative example of the hydrolysable metal compound includes hafnium methoxide, hafnium ethoxide, hafnium propoxide, hafnium butoxide, hafnium amyloxide, hafnium hexyloxide, hafnium cyclopentoxide, hafnium cyclohexyloxide, hafnium allyloxide, hafnium phenoxide, hafnium methoxyethoxide, hafnium ethoxyethoxide, hafnium dipropoxy bisethyl acetoacetate, hafnium dibutoxy bisethyl acetoacetate, hafnium dipropoxy bis 2,4-pentanedionate, and hafnium dibutoxy bis 2,4-pentanedionate as a monomer.

If L is bismuth, illustrative example of the hydrolysable metal compound includes methoxy bismuth, ethoxy bismuth, propoxy bismuth, butoxy bismuth, and phenoxy bismuth as a monomer.

If L is tin, illustrative example of the hydrolysable metal compound includes methoxy tin, ethoxy tin, propoxy tin, butoxy tin, phenoxy tin, methoxyethoxy tin, ethoxyethoxy tin, tin 2,4-pentanedionate, and tin 2,2,6,6-tetramethyl-3,5-heptanedionate as a monomer.

If L is phosphorous, illustrative example of the hydrolysable metal compound includes trimethyl phosphite, triethyl phosphite, tripropyl phosphite, trimethyl phosphate, triethyl phosphate, tripropyl phosphate, and diphosphorus pentoxide as a monomer.

If L is vanadium, illustrative example of the hydrolysable metal compound includes vanadium oxide-bis(2,4-pentanedionate), vanadium 2,4-pentanedionate, vanadium oxide tributoxide, and vanadium oxide tripropoxide as a monomer.

If L is arsenic, illustrative example of the hydrolysable metal compound include methoxy arsenic, ethoxy arsenic, propoxy arsenic, butoxy arsenic, and phenoxy arsenic as a monomer.

If L is antimony, illustrative example of the hydrolysable metal compound includes methoxy antimony, ethoxy antimony, propoxy antimony, butoxy antimony, phenoxy antimony, antimony acetate, and antimony propionate as a monomer.

If L is niobium, illustrative example of the hydrolysable metal compound includes methoxy niobium, ethoxy niobium, propoxy niobium, butoxy niobium, and phenoxy niobium as a monomer.

If L is tantalum, illustrative example of the hydrolysable metal compound includes methoxy tantalum, ethoxy tantalum, propoxy tantalum, butoxy tantalum, and phenoxy tantalum as a monomer.

A silicon-containing compound as the component (A) of the composition for forming a titanium-containing resist underlayer film of the present invention can be obtained by hydrolysis and/or condensation of one or more kinds of silicon compounds shown by the above general formula (A-I), preferably one or more kinds of silicon compounds shown by the above general formula (A-I) and one or more kinds of hydrolysable metal compounds shown by the above general formula (A-II).

The component (A) can be produced by selecting one or more kinds of the above monomers and by hydrolysis condensation of one or more kinds of compounds selected from an inorganic acid, an aliphatic sulfonic acid and an aromatic sulfonic acid as an acid catalyst.

Illustrative example of the acid catalyst used includes fluorinated acid, hydrochloric acid, hydrobromic acid, sulfuric acid, nitric acid, perchloric acid, phosphoric acid, methanesulfonic acid, benzenesulfonic acid, toluenesulfonic acid, formic acid, acetic acid, propionic acid, oxalic acid, and maleic acid. The catalyst is used in the range of 1×10⁻⁶ to 10 moles, preferably 1×10⁻⁵ to 5 moles, and more preferably 1×10⁻⁴ to 1 mole, per mole of a monomer.

The amount of water for obtaining a silicon-containing compound by hydrolyzing and condensing these monomers is preferably added in the range of 0.01 to 100 moles, more preferably 0.05 to 50 moles, and much more preferably 0.1 to 30 moles, per mole of a hydrolysable substituent linked to a monomer. If the amount is 100 moles or less, a reactor becomes smaller and more economical.

In operation, a monomer is added to a catalyst aqueous solution to start hydrolyzation and condensation reaction. An organic solvent may be added to the catalyst aqueous solution, and a monomer may be diluted with the organic solvent, or both may be performed. The reaction temperature is in the range of 0 to 100° C., and preferably 5 to 80° C. The reaction temperature is maintained in the range of 5 to 80° C. when a monomer is dropped, and then the mixture is preferably matured in the range of 20 to 80° C.

Illustrative example of the organic solvent that can be added to a catalyst aqueous solution or can dilute a monomer includes methanol, ethanol, 1-propanol, 2-propanol, 1-butanol, 2-butanol, 2-methyl-1-propanol, acetone, acetonitrile, tetrahydrofuran, toluene, hexane, ethyl acetate, acetonitrile, tetrahydrofuran, toluene, hexane, ethyl acetate, cyclohexanone, methyl amyl ketone, butanediol monomethyl ether, propylene glycolmonomethyl ether, ethylene glycolmonomethyl ether, butanediol monoethyl ether, propylene glycol monoethyl ether, ethylene glycol monoethyl ether, propylene glycoldimethyl ether, diethylene glycoldimethyl ether, propylene glycolmonomethyl ether acetate, propylene glycol monoethyl ether acetate, ethyl pyruvate, butyl acetate, methyl 3-methoxy propionate, ethyl 3-ethoxy propionate, t-butyl acetate, t-butyl propionate, propylene glycol mono-t-butylether acetate, γ-butyrolactone and a mixture thereof.

Illustrative example of these solvents includes a water-soluble solvent, e.g., an alcohol such as methanol, ethanol, 1-propanol, and 2-propanol; a polyvalent alcohol such as ethylene glycol and propylene glycol; a polyvalent alcohol condensate derivative such as butanediol monomethyl ether, propylene glycolmonomethyl ether, ethylene glycolmonomethyl ether, butanediol monoethyl ether, propylene glycol monoethyl ether, ethylene glycol monoethyl ether, butanediol monopropylether, propylene glycol monopropylether, and ethylene glycol monopropylether; acetone, acetonitrile; and tetrahydrofuran. Particularly preferable is a solvent with a boiling point of 100° C. or less.

The amount of the organic solvent used is in the range of 0 to 1,000 ml, and particularly preferable 0 to 500 ml, per mole of a monomer. If the amount is 1,000 ml or less, a reactor becomes smaller and more economical.

Then, a catalyst is subjected to neutralization reaction as required to obtain a reaction mixture aqueous solution. The amount of an alkaline substance to be used for neutralization is preferably 0.1 to 2 equivalents, relative to an acid used in the catalyst. The alkaline substance may be optionally selected if it is alkaline in water.

Subsequently, it is preferable that a by-product such as an alcohol produced by hydrolysis condensation reaction from the reaction mixture be removed under reduced pressure. The temperature for heating the reaction mixture is preferably in the range of 0 to 100° C., more preferably 10 to 90° C., and much more preferably 15 to 80° C., depending on the kind of an alcohol generated by reaction with an organic solvent added. The decompression degree is preferably an atmospheric pressure or less, more preferably 80 kPa or less under absolute pressure, and much more preferably 50 kPa or less under absolute pressure, depending on kinds of organic solvents and alcohol to be removed, ventilation, condensing apparatus and heating temperature. Despite a difficulty of exactly learning the amount of the alcohol to be removed, about more than 80% by mass of the alcohol generated is preferably removed.

Next, the acid catalyst used in hydrolysis condensation reaction may be removed from the reaction mixture. A method for removing an acid catalyst is to mix water and a reaction mixture and extract a silicon-containing compound with an organic solvent. Illustrative example of the organic solvent used includes the one that can dissolve a silicon-containing compound and achieve two-layer separation by mixing with water. Specific example thereof includes methanol, ethanol, 1-propanol, 2-propanol, 1-butanol, 2-butanol, 2-methyl-1-propanol, acetone, tetrahydrofuran, toluene, hexane, ethyl acetate, cyclohexanone, methyl amyl ketone, butanediol monomethyl ether, propylene glycolmonomethyl ether, ethylene glycolmonomethyl ether, butanediol monoethyl ether, propylene glycol monoethyl ether, ethylene glycol monoethyl ether, butanediol monopropylether, a propylene glycol monopropylether, ethylene glycol monopropylether, propylene glycoldimethyl ether, diethylene glycoldimethyl ether, propylene glycolmonomethyl ether acetate, propylene glycol monoethyl ether acetate, ethyl pyruvate, butyl acetate, methyl 3-methoxy propionate, ethyl 3-ethoxy propionate, t-butyl acetate, t-butyl propionate, propylene glycol mono-t-butylether acetate, γ-butyrolactone, methylisobutyl ketone, cyclopentylmethylether, and a mixture thereof.

Moreover, a mixture of a water-soluble organic solvent and a slightly water soluble organic solvent can be used. Illustrative example thereof includes methanol+ethyl acetate mixture, ethanol+ethyl acetate mixture, 1-propanol+ethyl acetate mixture, 2-propanol+ethyl acetate mixture, butanediol monomethyl ether+ethyl acetate mixture, propylene glycolmonomethyl ether+ethyl acetate mixture, ethylene glycolmonomethyl ether+ethyl acetate mixture, butanediol monoethyl ether+ethyl acetate mixture, propylene glycol monoethyl ether+ethyl acetate mixture, ethylene glycol monoethyl ether+ethyl acetate mixture, butanediol monopropylether+ethyl acetate mixture, propylene glycol monopropylether+ethyl acetate mixture, ethylene glycol monopropylether+ethyl acetate mixture, methanol+methylisobutyl ketone mixture, ethanol+methylisobutyl ketone mixture, 1-propanol+methylisobutyl ketone mixture, 2-propanol+methylisobutyl ketone mixture, propylene glycolmonomethyl ether+methylisobutyl ketone mixture, ethylene glycolmonomethyl ether+methylisobutyl ketone mixture, propylene glycol monoethyl ether+methylisobutyl ketone mixture, ethylene glycol monoethyl ether+methylisobutyl ketone mixture, propylene glycol monopropylether+methylisobutyl ketone mixture, ethylene glycol monopropylether+methylisobutyl ketone mixture, methanol+cyclopentylmethylether mixture, ethanol+cyclopentylmethylether mixture, 1-propanol+cyclopentylmethylether mixture, 2-propanol+cyclopentylmethylether mixture, propylene glycolmonomethyl ether+cyclopentylmethylether mixture, ethylene glycolmonomethyl ether+cyclopentylmethylether mixture, propylene glycol monoethyl ether+cyclopentylmethylether mixture, ethylene glycol monoethyl ether+cyclopentylmethylether mixture, propylene glycol monopropylether+cyclopentylmethylether mixture, ethylene glycol monopropylether+cyclopentylmethylether mixture, methanol+propylene glycolmethyl ether acetate mixture, ethanol+propylene glycolmethyl ether acetate mixture, 1-propanol+propylene glycolmethyl ether acetate mixture, 2-propanol+propylene glycolmethyl ether acetate mixture, propylene glycolmonomethyl ether+propylene glycolmethyl ether acetate mixture, ethylene glycolmonomethyl ether+propylene glycolmethyl ether acetate mixture, propylene glycol monoethyl ether+propylene glycolmethyl ether acetate mixture, ethylene glycol monoethyl ether+propylene glycolmethyl ether acetate mixture, propylene glycol monopropylether+propylene glycolmethyl ether acetate mixture, and ethylene glycol monopropylether+propylene glycolmethyl ether acetate mixture, but is not restricted to combination thereof.

The mixing ratio of the water-soluble organic solvent and the slightly water soluble organic solvent is determined accordingly. However, the water-soluble organic solvent is 0.1 to 1,000 parts by mass, preferably 1 to 500 parts by mass, and much more preferably 2 to 100 parts by mass, relative to 100 parts by mass of a slightly water soluble organic solvent.

Subsequently, the mixture of the water-soluble organic solvent and the slightly water soluble organic solvent may be cleaned with neutral water. The neutral water may be a deionized water or an ultrapure water. The amount of the water is 0.01 to 100 L, preferably 0.05 to 50 L, and more preferably 0.1 to 5 L, per L of a silicon-containing compound solution. The method for cleaning the mixture is to charge both solvents into the same container, agitate them and then allow them to stand to separate a water layer. The number of cleaning may be once or more, but preferably once to 5 times because 10 or more cleaning is not effective.

Other methods for removing an acid catalyst include a method by ion-exchange resin, and a method for removing an acid catalyst after neutralization with an epoxy compound such as an ethylene oxide and a propylene oxide. These methods can be selected according to the kind of an acid catalyst used in the reaction.

The water cleaning can allow part of a reaction mixture to move to and blend into a water layer, leading to fractionation effect. Therefore, the number of cleaning and the amount of cleaning water may be accordingly selected in view of catalyst-removing and fractionation effects.

As to both a reaction mixture having a residual acid catalyst and a reaction mixture solution having no more acid catalyst, a solvent is finally added thereto and a solvent is exchanged under reduced pressure to obtain a desired silicon-containing compound solution. The temperature for solvent exchange is preferably in the range of 0 to 100° C., more preferably 10 to 90° C., and much more preferably 15 to 80° C., depending on the kinds of reaction solvents to be removed and an extracting solvent. The decompression degree is preferably an atmospheric pressure or less, more preferably 80 kPa or less under absolute pressure, and much more preferably 50 kPa or less under absolute pressure, depending on the kinds of extracting solvent, ventilation, condensing apparatus, and heating temperature.

Accordingly, change in a solvent can labilize the reaction mixture. In order to prevent this labilization that is caused due to chemical affinity of the solvent and the reaction mixture, a monovalent, a divalent, or a more polyvalent alcohol having a cyclic ether as a substituent described at the paragraphs [0181] to [0182] of Japanese Patent Laid-Open Publication No. 2009-126940 may be added thereto as a stabilizer. The amount of the stabilizer to be added is in the range of 0 to 25 parts by mass, preferably 0 to 15 parts by mass, and more preferably 0 to 5 parts by mass, relative to 100 parts by mass of a reaction mixture in a solution before solvent exchange, but more than 0.5 parts by mass is most preferable in the case of addition the alcohol to the reaction mixture. A monovalent, a divalent, or a more polyvalent alcohol having cyclic ether as a substituent may be added to a solution, as required, to perform solvent exchange.

If a reaction mixture is concentrated with more than a certain level of concentration, condensation reaction will further proceed, so that it cannot be redissoluted in an organic solvent. Therefore, the concentration is preferably maintained at a proper level. If the concentration is too low to the contrary, the amount of a solvent is too large, thus a proper solution concentration is preferable in view of an economical advantage. The concentration is preferably in the range of 0.1 to 20% by mass.

Illustrative example of the solvent finally added to a reaction mixture solution includes a derivative of alcohol solvent, and particularly a derivative of monoalkyl ether such as ethylene glycol, diethylene glycol, triethylene glycol, propylene glycol, dipropylene glycol, and butanediol. Specifically, preferred example thereof includes butanediol monomethyl ether, propylene glycolmonomethyl ether, ethylene glycolmonomethyl ether, butanediol monoethyl ether, propylene glycol monoethyl ether, ethylene glycol monoethyl ether, butanediol monopropylether, propylene glycol monopropylether, and ethylene glycol monopropylether.

With these solvents as a main component, a non-alcohol solvent can be added as a co-solvent. Illustrative example of the co-solvent includes acetone, tetrahydrofuran, toluene, hexane, ethyl acetate, cyclohexanone, methyl amyl ketone, propylene glycoldimethyl ether, diethylene glycoldimethyl ether, propylene glycolmonomethyl ether acetate, propylene glycol monoethyl ether acetate, ethyl pyruvate, butyl acetate, methyl 3-methoxy propionate, ethyl 3-ethoxy propionate, t-butyl acetate, t-butyl propionate, propylene glycol mono-t-butylether acetate, γ-butyrolactone, methylisobutyl ketone, and cyclopentylmethylether.

In another operation by using an acid catalyst, water or a water-containing organic solvent is added to a monomer or an organic solution of a monomer to start hydrolysis reaction. The catalyst may be added to a monomer or an organic solution of a monomer or added to water or a water-containing organic solvent. The reaction temperature is in the range of 0 to 100° C., and preferably 10 to 80° C. A method for heating a mixture at 10 to 50° C. when water is dropped and then heating the mixture at 20 to 80° C. to mature the mixture is preferable.

Illustrative example of the organic solvent includes a water-soluble solvent, e.g. a condensate derivative of polyvalent alcohol such as methanol, ethanol, 1-propanol, 2-propanol, 1-butanol, 2-butanol, 2-methyl-1-propanol, acetone, tetrahydrofuran, acetonitrile, butanediol monomethyl ether, propylene glycolmonomethyl ether, ethylene glycolmonomethyl ether, butanediol monoethyl ether, propylene glycol monoethyl ether, ethylene glycol monoethyl ether, butanediol monopropylether, propylene glycol monopropylether, ethylene glycol monopropylether, propylene glycoldimethyl ether, diethylene glycoldimethyl ether, propylene glycolmonomethyl ether acetate, propylene glycol monoethyl ether acetate, and propylene glycol monopropylether, and a mixture thereof.

The amount of the organic solvent used may be the same as before. A reaction mixture obtained is post-treated like the method to obtain a silicon-containing compound.

The silicon-containing compound of the component (A) can be obtained by hydrolyzing and condensing a monomer in the presence of a base catalyst. Illustrative example of the alkali catalyst used includes methylamine, ethylamine, propylamine, butylamine, ethylenediamine, hexamethylene diamine, dimethylamine, diethylamine, ethylmethylamine, trimethylamine, triethylamine, tripropylamine, tributylamine, cyclohexylamine, dicyclohexylamine, monoethanolamine, diethanolamine, dimethyl monoethanolamine, monomethyl diethanolamine, triethanolamine, diazabicyclo octane, diazabicyclo cyclononene, diazabicyclo undecene, hexamethylene tetramine, aniline, N,N-dimethylaniline, pyridine, N,N-dimethylaminopyridine, pyrrole, piperazine, pyrrolidine, piperidine, picoline, tetramethylammonium hydroxide, choline hydroxide, tetrapropylammonium hydroxide, tetrabutylammonium hydroxide, ammonia, lithium hydroxide, sodium hydroxide, potassium hydroxide, barium hydroxide, and calcium hydroxide. The amount of the catalyst used is in the range of 1×10⁻⁶ to 10 moles, preferably 1×10⁻⁵ to 5 moles, and more preferably 1×10⁻⁴ to 1 moles, per mole of a silicon monomer.

The amount of water for obtaining a silicon-containing compound by hydrolyzing and condensing the above monomers is preferably in the range of 0.1 to 50 moles to be added, per mole of a hydrolysable substituent bonded to the monomers. If the amount is 50 moles or less, a reactor becomes smaller and more economical.

In operation, a monomer is added to a catalyst solution to start hydrolysis condensation reaction. An organic solvent may be added to a catalyst solution, a monomer may be diluted with an organic solvent, or both may be performed. The reaction temperature is in the range of 0 to 100° C., and preferably 5 to 80° C. A method for maintaining the temperature at 5 to 80° C. when a monomer is dropped and then aging the mixture at 20 to 80° C. is preferable.

The organic solvent used that can be added to a base catalyst solution or can dilute a monomer is preferably an illustrative example of the organic solvent that can be added to an acid catalyst solution as described above. The amount of the organic solvent used is preferably in the range of 0 to 1,000 ml, per mole of a monomer, due to economical reaction.

As required, a catalyst is subjected to neutralization reaction afterward to obtain a reaction mixture aqueous solution. The amount of an acid material used for neutralization is preferably in the range of 0.1 to 2 equivalents, relative to a base substance used in the catalyst. The acid material may be optionally selected if it is acid in water.

Subsequently, it is preferable that a by-product such as an alcohol produced by hydrolysis condensation reaction from the reaction mixture be removed under reduced pressure. The temperature for heating the reaction mixture is preferably in the range of 0 to 100° C., more preferably 10 to 90° C., and much more preferably 15 to 80° C., depending on the kind of an alcohol generated by reaction with an organic solvent added. The decompression degree is preferably an atmospheric pressure or less, more preferably 80 kPa or less under absolute pressure, and much more preferably 50 kPa or less under absolute pressure, depending on kinds of organic solvents and alcohol to be removed, ventilation, condensing apparatus and heating temperature. Despite a difficulty of exactly learning the amount of the alcohol to be removed, about more than 80% by mass of the alcohol generated is preferably removed.

Next, to remove the catalyst used in hydrolysis condensation reaction, a reaction mixture is extracted with an organic solvent. The organic solvent used can preferably dissolve a reaction mixture and achieve two-layer separation by mixing with water.

Moreover, a mixture of a water-soluble organic solvent and a slightly water soluble organic solvent can be used as an organic solvent used for removing a base catalyst.

Illustrative example of the organic solvent used for removing a base catalyst includes the above-mentioned organic solvent for removing the acid catalyst, and a mixture of a water-soluble organic solvent and a slightly water soluble organic solvent.

The mixing ratio of the water-soluble organic solvent and the slightly water soluble organic solvent is determined accordingly. However, the water-soluble organic solvent is 0.1 to 1,000 parts by mass, preferably 1 to 500 parts by mass, and much more preferably 2 to 100 parts by mass, relative to 100 parts by mass of a slightly water soluble organic solvent.

Subsequently, the mixture of the water-soluble organic solvent and the slightly water soluble organic solvent may be cleaned with neutral water. The neutral water may be a deionized water or an ultrapure water. The amount of the water is 0.01 to 100 L, preferably 0.05 to 50 L, and more preferably 0.1 to 5 L, per L of a reaction mixture solution. The method for cleaning the mixture is to charge both solvents into the same container, agitate them and then allow them to stand to separate water layer. The number of cleaning may be once or more, but preferably once to 5 times because 10 or more cleaning is not effective.

A solvent is finally added to a cleaned reaction mixture solution and solvent is exchanged under reduced pressure to obtain a desired silicon-containing compound solution. The temperature for solvent exchange is preferably in the range of 0 to 100° C., more preferably 10 to 90° C., and much more preferably 15 to 80° C., depending on the kinds of reaction solvents to be removed and an extracting solvent. The decompression degree is preferably an atmospheric pressure or less, more preferably 80 kPa or less under absolute pressure, and much more preferably 50 kPa or less under absolute pressure, depending on the kinds of extracting solvent, ventilation, condensing apparatus, and heating temperature.

Illustrative example of the solvent finally added to a reaction mixture includes an alcohol solvent and a derivative thereof, and particularly a monoalkyl ether such as ethylene glycol, diethylene glycol, and triethylene glycol; and a monoalkyl ether such as propylene glycol and dipropylene glycol. Illustrative example thereof includes propylene glycolmonomethyl ether, ethylene glycolmonomethyl ether, propylene glycol monoethyl ether, ethylene glycol monoethyl ether, propylene glycol monopropylether, and ethylene glycol monopropylether.

In another operation by using a base catalyst, water or a water-containing organic solvent is added to a monomer or an organic solution of a monomer to start hydrolysis reaction. The catalyst may be added to a monomer or an organic solution of a monomer or added to water or a water-containing organic solvent. The reaction temperature is in the range of 0 to 100° C., and preferably 10 to 80° C. A method for heating a mixture at 10 to 50° C. when water is dropped and then heating the mixture at 20 to 80° C. to mature the mixture is preferable.

The organic solvent is preferably a water-soluble solvent and illustrative example thereof a polyvalent alcohol condensate derivative such as methanol, ethanol, a 1-propanol, 2-propanol, 1-butanol, 2-butanol, 2-methyl-1-propanol, acetone, tetrahydrofuran, acetonitrile, propylene glycolmonomethyl ether, ethylene glycolmonomethyl ether, propylene glycol monoethyl ether, ethylene glycol monoethyl ether, propylene glycol monopropylether, ethylene glycol monopropylether, propylene glycoldimethyl ether, diethylene glycoldimethyl ether, propylene glycolmonomethyl ether acetate, propylene glycol monoethyl ether acetate, and propylene glycol monopropylether, and a mixture thereof.

The molecular weight of the silicon-containing compound obtained can be adjusted not only by selecting a monomer, but also controlling reaction conditions during polymerization. However, if the average molecular weight is 100,000 or less, the silicon-containing compound could preferably show no foreign object or coating spot. The average molecular weight is more preferably 200 to 50,000, and much more preferably 300 to 30,000.

The above average molecular weight is obtained as data, in terms of polystyrene as a reference material, by means of gel-permeation chromatography (GPO) by using RI as a detector and tetrahydrofuran as an eluant.

The component (A) whose surface free energy is lower than that of a later-described component (B) can provide a resist underlayer film with favorable pattern adhesiveness without reducing the etching selectivity in a 2-layer structure having no sea-island structure when a resist underlayer film is formed.

### Component (B)

Illustrative example of the raw material of a titanium-containing compound as component (B) of the composition for forming a titanium-containing resist underlayer film of the present invention can include one or more kinds of hydrolysable titanium compounds shown by the following general formula (B-I),

Ti(OR^{0B})₄ (B-I)

wherein, R^{0B} represents an organic group having 1 to 10 carbon atoms.

Illustrative example of the hydrolysable titanium compound includes a titanium methoxide, a titanium ethoxide, a titanium propoxide, a titanium butoxide, a titanium amyloxide, a titanium hexyloxide, a titanium cyclopentoxide, a titanium cyclohexyloxide, a titanium allyloxide, a titanium phenoxide, a titanium methoxyethoxide, a titanium ethoxyethoxide, a titanium dipropoxy bisethyl acetoacetate, a titanium dibutoxy bisethyl acetoacetate, a titanium dipropoxy bis 2,4-pentanedionate, a titanium dibutoxy bis 2,4-pentanedionate and an oligomer as a partial hydrolytic condensate thereof.

As the component (B) of the composition for forming a titanium-containing resist underlayer film of the present invention, the titanium-containing compound can be obtained by hydrolyzing and/or condensing the above hydrolysable titanium compound using no catalyst, or in the presence of acid or alkali catalyst. A method for producing the titanium-containing compound by hydrolysis condensation by using one or more kinds of compounds selected from inorganic acid, aliphatic sulfonic acid, aromatic sulfonic acid, an aliphatic carboxylic acid and an aromatic carboxylic acid as an acid catalyst.

Illustrative example of the acid catalyst used includes an acid such as fluorinated acid, hydrochloric acid, hydrobromic acid, sulfuric acid, nitric acid, perchloric acid, phosphoric acid, methanesulfonic acid, benzenesulfonic acid, toluenesulfonic acid, formic acid, acetic acid, propionic acid, oxalic acid, malonic acid, maleic acid, fumaric acid, and benzoic acid. The catalyst is used in the range of 1×10⁻⁶ to 10 moles, preferably 1×10⁻⁵ to 5 moles, and more preferably 1×10⁻⁴ to 1 mole, per mole of a monomer.

A titanium compound may be produced by hydrolysis condensation in the presence of a base catalyst. Illustrative example of the base catalyst used includes methylamine, ethylamine, propylamine, butylamine, ethylenediamine, hexamethylene diamine, dimethylamine, diethylamine, ethylmethylamine, trimethylamine, triethylamine, tripropylamine, tributylamine, cyclohexylamine, dicyclohexylamine, monoethanolamine, diethanolamine, dimethyl monoethanolamine, monomethyl diethanolamine, triethanolamine, diazabicyclo octane, diazabicyclo cyclononene, diazabicyclo undecene, hexamethylene tetramine, aniline, N,N-dimethylaniline, pyridine, N,N-dimethylethanolamine, N,N-diethylethanolamine, N-(β-aminoethyl)ethanolamine, N-methylethanolamine, N-methyldiethanolamine, N-ethylethanolamine, N-n-butylethanolamine, N-n-butyldiethanolamine, N-tert-butylethanolamine, N-tert-butyldiethanolamine, N,N-dimethylaminopyridine, pyrrole, piperazine, pyrrolidine, piperidine, picoline, tetramethylammonium hydroxide, choline hydroxide, tetrapropylammonium hydroxide, tetrabutylammonium hydroxide, ammonia, lithium hydroxide, sodium hydroxide, potassium hydroxide, barium hydroxide, and calcium hydroxide. The amount of the catalyst used is in the range of 1×10⁻⁶ to 10 moles, preferably 1×10⁻⁵ to 5 moles, and more preferably 1×10⁻⁴ to 1 moles, per mole of a titanium monomer.

By hydrolysis condensation of the above titanium compound, the amount of water used for obtaining a titanium-containing compound is preferably added with 0.01 to 10 moles, more preferably 0.05 to 5 moles, and much more preferably 0.1 to 3 moles, per mole of hydrolysable substituent linked to titanium-containing compound. If the amount is 10 moles or less, the reaction apparatus can be smaller and economical, and the stability of the titanium-containing compound is not reduced.

In operation, a titanium compound is added to a catalyst aqueous solution to start hydrolysis condensation reaction. An organic solvent may be added to a catalyst aqueous solution or a titanium compound may be dilute with an organic solvent, or both may be performed. The reaction temperature is preferably 0 to 200° C., more preferably 5 to 150° C. A method for maintaining the temperature at 5 to 150° C. when the titanium compound is dropped and then mature at 20 to 150° C. is preferable.

In another operation, water or a water-containing organic solvent is added to a titanium compound or an organic solution of a titanium compound to start hydrolysis reaction. A catalyst may be added to a titanium compound or an organic solution of a titanium compound, or added to water or a water-containing organic solvent. The reaction temperature is preferably 0 to 200° C., more preferably 5 to 150° C. A method for maintaining the temperature at 5 to 150° C. when the titanium compound is dropped and then mature at 20 to 150° C. is preferable titanium compound.

Illustrative example of the organic solvent that can be added to a catalyst aqueous solution or can dilute a titanium-containing compound includes methanol, ethanol, 1-propanol, 2-propanol, 1-butanol, 2-butanol, 2-methyl-1-propanol, acetone, acetonitrile, tetrahydrofuran, toluene, hexane, ethyl acetate, cyclohexanone, methyl amyl ketone, butanediol monomethyl ether, propylene glycolmonomethyl ether, ethylene glycolmonomethyl ether, butanediol monoethyl ether, propylene glycol monoethyl ether, ethylene glycol monoethyl ether, propylene glycoldimethyl ether, diethylene glycoldimethyl ether, propylene glycolmonomethyl ether acetate, propylene glycol monoethyl ether acetate, ethyl pyruvate, butyl acetate, methyl 3-methoxy propionate, ethyl 3-ethoxy propionate, t-butyl acetate, t-butyl propionate, propylene glycol mono-t-butylether acetate, γ-butyrolactone, acetylacetone, methyl acetoacetate, ethyl acetoacetate, propyl acetoacetate, butyl acetoacetate, methylpivaloyl acetate, methylisobutyloyl acetate, methyl caproyl acetate, methyl lauroyl acetate, 1,2-ethanediol, 1,2-propanediol, 1,2-butanediol, 1,2-pentanediol, 2,3-butanediol, 2,3-pentanediol, glycerin, diethylene glycol, hexylene glycol, and a mixture thereof.

The amount of the organic solvent used is preferably 0 to 1,000 ml, particularly 0 to 500 ml per mole of a titanium-containing compound. If the amount is 1,000 ml or less, the reaction container can be made smaller and economical.

Thereafter, a catalyst is subjected to neutralization as required and an alcohol generated in hydrolysis condensation reaction is removed under reduced pressure to obtain a reaction mixture solution. The amounts of an acid and a base used for neutralization are preferably 0.1 to 2 equivalents, relative to an acid and a base used in catalyst, respectively, and if each of them is neutral, it may be an optional substance.

Subsequently, a by-product such as an alcohol generated in hydrolysis condensation reaction is preferably removed from a reaction mixture. The temperature for heating a reaction mixture is determined by the type of an alcohol generated by an organic solvent added, but preferably 0 to 200° C., more preferably 10 to 150° C., much more preferably 15 to 150° C. The reduced pressure depending on the kinds of an organic solvent and alcohol removed, ventilation, condensing apparatus, and heating temperature is preferably an atmosphere pressure or less, preferably 80 kPa or less at absolute pressure, more preferably 50 kPa or less at absolute pressure. It is difficult to exactly learn the amount of an alcohol removed, and about 80% by mass or more of an alcohol generated is preferably removed.

A solvent is finally added to a reaction mixture solution thus obtained and a solvent is exchanged under reduced pressure to obtain a titanium-containing compound solution.

Illustrative example of the above solvent includes butanediol monomethyl ether, propylene glycolmonomethyl ether, ethylene glycolmonomethyl ether, butanediol monoethyl ether, propylene glycol monoethyl ether, ethylene glycol monoethyl ether, butanediol monopropylether, propylene glycol monopropylether, ethylene glycol monopropylether, ethylene glycol monobutyl ether, diethylene glycol monomethyl ether, diethylene glycol monoethyl ether, diethylene glycol monopropylether, diethylene glycol monobutyl ether, propylene glycol monobutyl ether, 1-butanol, 2-butanol, 2-methyl-1-propanol, 4-methyl-2-pentanol, acetone, tetrahydrofuran, toluene, hexane, ethyl acetate, cyclohexanone, methyl amyl ketone, propylene glycoldimethyl ether, diethylene glycoldimethyl ether, diamyl ether, propylene glycol monomethyl ether acetate, propylene glycolmonoethyl ether acetate, ethyl pyruvate, butyl acetate, methyl 3-methoxy propionate, ethyl 3-ethoxy propionate, t-butyl acetate, t-butyl propionate, propylene glycol mono-t-butylether acetate, γ-butyrolactone, methyl isobutyl ketone, and cyclopentyl methyl ether.

The molecular weight of a titanium-containing compound obtained can be adjusted not only by selecting a titanium-containing compound but also controlling reaction conditions during hydrolysis condensation, and the weight average molecular weight is preferably 100,000 or less, more preferably 200 to 50,000, and much more 300 to 30,000. If the average molecular weight is 100,000 or less, the titanium-containing compound could preferably show no foreign object or coating spot.

The component (B) whose surface free energy is higher than that of the above component (A) can provide a resist underlayer film with favorable etching selectivity in a 2-layer structure having no sea-island structure when a resist underlayer film is formed.

In the composition for forming a titanium-containing resist underlayer film of the present invention, the rate of the component (A) relative to the total of the above component (A) and component (B) is preferably 20% by mass or less, more preferably 15% by mass or less. With the rate, it is preferable that the etching selectivity of a titanium-containing resist underlayer film relative to an organic film and a silicon-containing film be sufficiently obtained.

### Other Components

A photoacid generator may be added to the composition for forming a titanium-containing resist underlayer film of the present invention. As the photoacid generator, a composition described at the paragraphs [0160] to [0179] of Japanese Patent Laid-Open Publication No. 2009-126940 can be used.

A thermal acid generator may be added to the composition for forming a titanium-containing resist underlayer film of the present invention. As the thermal acid generator, a composition described at the paragraphs [0061] to [0085] of Japanese Patent Laid-Open Publication No. 2007-199653 can be used.

Accordingly, if a photoacid generator and a thermal acid generator are added to the composition for forming titanium-containing resist underlayer film of the present invention, the resolution of a pattern can be improved in addition to the above characteristics.

Moreover, the composition for forming a titanium-containing resist underlayer film of the present invention can be blended into a surfactant as required. As such, a composition described at the paragraph [0129] of Japanese Patent Laid-Open Publication No. 2009-126940 can be used.

By producing the composition for forming titanium-containing resist underlayer film of the present invention in this manner to form a resist underlayer film by using the same, a 2-layer structure in which a component (A) having a lower surface free energy is partially present on a surface is provided with no sea-island structure, thereby providing an excellent pattern adhesiveness and an etching selectivity at the same time to obtain fine pattern.

### Patterning Process

The following methods are provided as one embodiment of the patterning process of the present invention by using a titanium-containing resist underlayer film composition produced as above.

The present invention provides a patterning process to form a pattern on a body to be processed, wherein an organic underlayer film is formed on a body to be processed by using an application-type composition for the organic underlayer film, on the organic underlayer film is formed a titanium-containing resist underlayer film by using the composition for forming the titanium-containing resist underlayer film, on the titanium-containing resist underlayer film is formed a photoresist film by using a chemically amplified resist composition, the photoresist film is exposed to a high energy beam after heat treatment, a positive pattern is formed by dissolving an exposed area of the photoresist film by using an alkaline developer, pattern transfer is made onto the titanium-containing resist underlayer film by using the photoresist film having the positive pattern as a mask, pattern transfer is made onto the organic underlayer film by using the titanium-containing resist underlayer film having the transferred pattern as a mask, and then pattern transfer is made onto the body to be processed by using the organic underlayer film having the transferred pattern as a mask.

Another embodiment of the patterning process of the present invention is a patterning process to form a pattern on a body to be processed, wherein an organic hard mask mainly comprising carbon is formed on a body to be processed by a CVD method, on the organic hard mask is formed a titanium-containing resist underlayer film by using the composition for forming the titanium-containing resist underlayer film, on the titanium-containing resist underlayer film is formed a photoresist film by using a chemically amplified resist composition, the photoresist film is exposed to a high energy beam after heat treatment, a positive pattern is formed by dissolving an exposed area of the photoresist film by using an alkaline developer, pattern transfer is made onto the titanium-containing resist underlayer film by using the photoresist film having the positive pattern as a mask, pattern transfer is made onto the organic hard mask by using the titanium-containing resist underlayer film having the transferred pattern as a mask, and then pattern transfer is made onto the body to be processed by using the organic hard mask having the transferred pattern as a mask.

Another embodiment of the patterning process of the present invention is a patterning process to form a pattern on a body to be processed, wherein an organic underlayer film is formed on a body to be processed by using an application-type composition for the organic underlayer film, on the organic underlayer film is formed a titanium-containing resist underlayer film by using the composition for forming the titanium-containing resist underlayer film, on the titanium-containing resist underlayer film is formed a photoresist film by using a chemically amplified resist composition, the photoresist film is exposed to a high energy beam after heat treatment, a negative pattern is formed by dissolving an unexposed area of the photoresist film by using an organic solvent developer, pattern transfer is made onto the titanium-containing resist underlayer film by using the photoresist film having the negative pattern as a mask, pattern transfer is made onto the organic underlayer film by using the titanium-containing resist underlayer film having the transferred pattern as a mask, and then pattern transfer is made onto the body to be processed by using the organic underlayer film having the transferred pattern as a mask.

Another embodiment of the patterning process of the present invention is a patterning process to form a pattern on a body to be processed, wherein an organic hard mask mainly comprising carbon is formed on a body to be processed by a CVD method, on the organic hard mask is formed a titanium-containing resist underlayer film by using the composition for forming the titanium-containing resist underlayer film, on the titanium-containing resist underlayer film is formed a photoresist film by using a chemically amplified resist composition, the photoresist film is exposed to a high energy beam after heat treatment, a negative pattern is formed by dissolving an unexposed area of the photoresist film by using an organic solvent developer, pattern transfer is made onto the titanium-containing resist underlayer film by using the photoresist film having the negative pattern as a mask, pattern transfer is made onto the organic hard mask by using the titanium-containing resist underlayer film having the transferred pattern as a mask, and then pattern transfer is made onto the body to be processed by using the organic hard mask having the transferred pattern as a mask.

Herein, the body to be processed is preferably a semiconductor substrate coated, as a layer to be processed (a portion to be processed), with any of a metal film, a metal carbide film, a metal oxide film, a metal nitride film, a metal oxycarbide film, and a metal oxynitride film.

The semiconductor substrate is normally a silicon substrate, but is not particularly restricted thereto, and Si, amorphous silicon (α-Si), p-Si, SiO₂, SiN, SiON, W, Tin, and Al may be used as a composition that is different from a layer to be processed.

A metal that constitutes the body to be processed can be any of silicon, titanium, tungsten, hafnium, zirconium, chromium, germanium, copper, aluminum, and iron, or an alloy of these metals. Illustrative example of the layer to be processed containing the metal includes Si, SiO₂, SiN, SiON, SiOC, p-Si, α-Si, TiN, WSi, BPSG, SOG, Cr, CrO, CrON, MoSi, W, W—Si, Al, Cu, and Al—Si, various low-dielectric films, and its etching stopper films, and the metal can normally be formed with a thickness of 50 to 10,000 nm, particularly 100 to 5,000 nm.

A later-described titanium-containing resist underlayer film can be formed on the body to be processed in advance and an organic underlayer film or an organic hard mask can be formed thereon.

The titanium-containing resist underlayer film according to the present invention can be formed on a body to be processed from the above-mentioned composition for forming a titanium-containing resist underlayer film by using spin-coating method, on an organic underlayer film formed on the body to be processed, or on an organic hard mask formed on the body to be processed. After the titanium-containing resist underlayer film is formed by spin-coating method to provide a 2-layer structure, it is preferable that a solvent be evaporated and the resist underlayer film be baked to promote crosslinking reaction in order to prevent mixing with a resist upper layer film. Preferably, the baking temperature is in the range of 50 to 500° C. and the baking duration is in the range of 10 to 300 seconds. More preferably, the temperature is 400° C. or less to control thermal damage to devices, depending on the structure of a device produced. A method for the titanium-containing resist underlayer film of the present invention is not restricted to a spin-coating method, but a CVD method or an ALD method can be used.

The patterning process of the present invention can include a step of removing a residue of the titanium-containing resist underlayer film by wet stripping the same after transferring a pattern of the titanium-containing resist underlayer film on an underlayer. In this step, a stripping solution containing hydrogen peroxide is preferably used. In this case, pH is more preferably adjusted by adding an acid or an alkali to promote stripping. Illustrative example of the pH adjuster includes an inorganic acid such as hydrochloric acid and sulfuric acid, an organic acid such as acetic acid, oxalic acid, tartaric acid, citric acid, and lactic acid, alkali containing nitrogen such as ammonia, ethanolamine, tetramethyl ammonium hydroxide, and an organic acid compound containing nitrogen such as EDTA (ethylene diamine 4 acetic acid).

As a condition of wet stripping, a stripping solution of 0 to 80° C., preferably 5 to 60° C. is prepared and a body to be processed in which a titanium-containing resist underlayer film is formed (to be treated) may be immersed therein. A titanium-containing resist underlayer film can be readily removed according to specific procedures such as spraying a surface with a stripping solution and applying the stripping solution while rotating a body to be processed as required.

In the patterning process of the present invention, a photoresist film is not particularly restricted if it is formed by using a resist composition of a chemically amplified type, and as required, an upper layer top coat can be formed on a photoresist film.

When the photoresist film is exposed by a high energy beam, the photoresist film is preferably exposed by any of the method of photolithography with a wavelength of 300 nm or less or an EUV beam or the method of a direct drawing with an electron beam. Accordingly, by photolithography by using a wavelength of 300 nm or less or EUV beam, fine patterning can be achieved on a body to be processed and use of lithography by using an EUV beam in particular can produce a 32-node device.

A photoresist film after exposure can be positive patterned by dissolving an exposed area by using an alkaline developer, or can be negative patterned by dissolving a non-exposed area by using a developer composed of an organic solvent.

Illustrative example of the alkaline developer includes tetramethylammonium hydroxide (TMAH).

Illustrative example of the developer of the organic solvent includes a developer containing one or more components selected from 2-octanone, 2-nonanone, 2-heptanone, 3-heptanone, 4-heptanone, 2-hexanone, 3-hexanone, diisobutyl ketone, methylcyclohexanone, acetophenone, methyl acetophenone, propyl acetate, butyl acetate, isobutyl acetate, amyl acetate, butenyl acetate, isoamyl acetate, phenyl acetate, propyl formate, butyl formate, isobutyl formate, amyl formate, isoamyl formate, methyl valerate, methyl pentenoate, methyl crotonate, ethyl crotonate, methyl lactate, ethyl lactate, propyl lactate, butyl lactate, isobutyl lactate, amyl lactate, isoamyl lactate, methyl 2-hydroxyisobutyrate, ethyl 2-hydroxyisobutyrate, methyl benzoate, ethyl benzoate, phenyl acetate, benzyl acetate, methyl phenyl acetate, benzyl formate, phenylethyl formate, 3-phenylmethyl propionate, benzyl propionate, ethyl phenyl acetate, and 2-phenylethyl acetate, and the total content of the one or more components in the developer is preferably more than 50% by mass to prevent pattern collapse.

The patterning process is excellent in pattern adhesiveness and etching selectivity of a resist underlayer film relative to a photoresist film organic underlayer film and an organic hard mask and a pattern can be transferred on a body to be processed without size conversion difference even if fine pattern is formed on a photoresist film.

### EXAMPLE

The present invention will be specifically described with reference to Synthesis Examples, Examples and Comparative Examples, but it is not restricted thereto. “%” in the following Examples represents “% by mass,” and the molecular weight is measured by GPC.

### Synthesis of Component (A)

### Synthesis Example A-I

[Monomer 101] (68.1 g) was added to a mixture of a methanol (200 g), methanesulfonic acid (0.1 g) and deionized water (60 g) and the temperature was maintained at 40° C. for 12 hours to be subjected to hydrolysis condensation. After completion of the reaction, propylene glycol methyl ether acetate (PGMEA) (200 g) was added thereto to remove by-product alcohol under reduced pressure. Ethyl acetate (1000 ml) and PGMEA (300 g) were added thereto to separate a water layer. Ion-exchange water (100 ml) was added to a remaining organic layer to be agitated, allowed to stand and separated. This step was repeated 3 times and the remaining organic layer was concentrated under reduced pressure to obtain PGMEA solution of silicon-containing compound A-I (170 g) (compound concentration: 20%). The molecular weight (Mw) of the compound measured in terms of polystyrene was 2,500.

Synthesis Examples A-2 to A-20 were carried out to each obtain the target compound by using monomers shown in Table 1 on the same condition as Synthesis Example A-1.

### Synthesis Example A-21

Mixture of [Monomer 101] (54.5 g) and [Monomer 131] (31.4 g) was added to a mixture of ethanol (400 g), 25% tetramethyl ammonium hydroxide (TMAH) (5 g) and deionized water (200 g) and the temperature was maintained at 40° C. for 4 hours to be subjected to hydrolysis condensation. After completion of the reaction, acetic acid (2 g) was added thereto for neutralization to remove by-product alcohol under reduced pressure. Ethyl acetate (1200 ml) and PGMEA (400 g) were added thereto to separate a water layer. Ion-exchange water (100 ml) was added to a remaining organic layer to be agitated, allowed to stand and separated. This step was repeated 3 times and the remaining organic layer was concentrated under reduced pressure to obtain PGMEA solution of a silicon-containing compound (A-21) (260 g) (compound concentration: 20%). The molecular weight (Mw) of the compound measured in terms of polystyrene was 1,900.

Synthesis Examples A-22 to A-23 were carried out to each obtain the target compound by using monomers shown in Table 1 on the same condition as Synthesis Example A-21.

TABLE 1

| Synthesis | | |
|---|---|---|
| Example | Raw material | Mw |
| A-1 | [Monomer 101]: 68.1 g | 2500 |
| A-2 | [Monomer 100]: 29.7 g, [Monomer 101]: 47.7 g | 2400 |
| A-3 | [Monomer 100]: 19.8 g, [Monomer 101]: 27.2 g, | 2200 |
| | [Monomer 102]: 30.4 g | |
| A-4 | [Monomer 101]: 27.2 g, [Monomer 102]: 22.8 g, | 2400 |
| | [Monomer 120]: 44.8 g | |
| A-5 | [Monomer 101]: 13.6 g, [Monomer 102]: 38.1 g, | 1900 |
| | [Monomer 121]: 49.6 g | |
| A-6 | [Monomer 101]: 13.6 g, [Monomer 102]: 38.1 g, | 2500 |
| | [Monomer 122]: 40.6 g | |
| A-7 | [Monomer 101]: 27.2 g, [Monomer 102]: 22.8 g, | 2200 |
| | [Monomer 123]: 46.9 g | |
| A-8 | [Monomer 101]: 13.6 g, [Monomer 102]: 38.1 g, | 2300 |
| | [Monomer 124]: 49.0 g | |
| A-9 | [Monomer 101]: 13.6 g, [Monomer 102]: 38.1 g, | 2100 |
| | [Monomer 125]: 40.6 g | |
| A-10 | [Monomer 101]: 13.6 g, [Monomer 102]: 38.1 g, | 2500 |
| | [Monomer 126]: 51.4 g | |
| A-11 | [Monomer 101]: 13.6 g, [Monomer 102]: 38.1 g, | 2800 |
| | [Monomer 127]: 41.8 g | |
| A-12 | [Monomer 101]: 34.1 g, [Monomer 102]: 15.2 g, | 2800 |
| | [Monomer 128]: 47.5 g | |
| A-13 | [Monomer 101]: 40.9 g, [Monomer 120]: 44.8 g, | 1900 |
| | [Monomer 129]: 12.7 g | |
| A-14 | [Monomer 101]: 40.9 g, [Monomer 122]: 40.6 g, | 2100 |
| | [Monomer 130]: 12.4 g | |
| A-15 | [Monomer 101]: 40.9 g, [Monomer 123]: 49.0 g, | 2700 |
| | [Monomer 129]: 12.7 g, [Monomer 130]: 12.4 g | |
| A-16 | [Monomer 100]: 14.9 g, [Monomer 101]: 40.9 g, | 1900 |
| | [Monomer 110]: 23.5 g | |
| A-17 | [Monomer 100]: 14.9 g, [Monomer 101]: 40.9 g, | 2300 |
| | [Monomer 111]: 42.5 g | |
| A-18 | [Monomer 100]: 14.9 g, [Monomer 101]: 40.9 g, | 2200 |
| | [Monomer 112]: 45.6 g | |
| A-19 | [Monomer 101]: 40.9 g, [Monomer 104]: 15.9 g, | 2100 |
| | [Monomer 113]: 35.5 g | |
| A-20 | [Monomer 101]: 40.9 g, [Monomer 105]: 17.1 g, | 2600 |
| | [Monomer 114]: 40.5 g | |
| A-21 | [Monomer 101]: 54.5 g, [Monomer 131]: 31.4 g | 1900 |
| A-22 | [Monomer 101]: 54.5 g, [Monomer 102]: 7.6 g, | 2100 |
| | [Monomer 132]: 13.2 g | |
| A-23 | [Monomer 101]: 54.5 g, [Monomer 102]: 7.6 g, | 2500 |
| | [Monomer 133]: 15.9 g | |

### PhSi(OCH₃)₃: [Monomer 100] CH₃Si(OCH₃)₃: [Monomer 101]

### Si(OCH₃)₄: [Monomer 102]

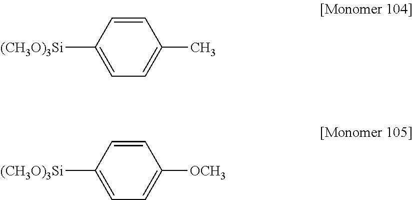

### B(OC₃H₇)₃: [Monomer 110] Ti(OC₄H₉)₄: [Monomer 111]

### Ge(OC₄H₉)₄: [Monomer 112] P₂O₅: [Monomer 113]

### Al[CH₃COCH═C(O—)CH₃]₃: [Monomer 114]

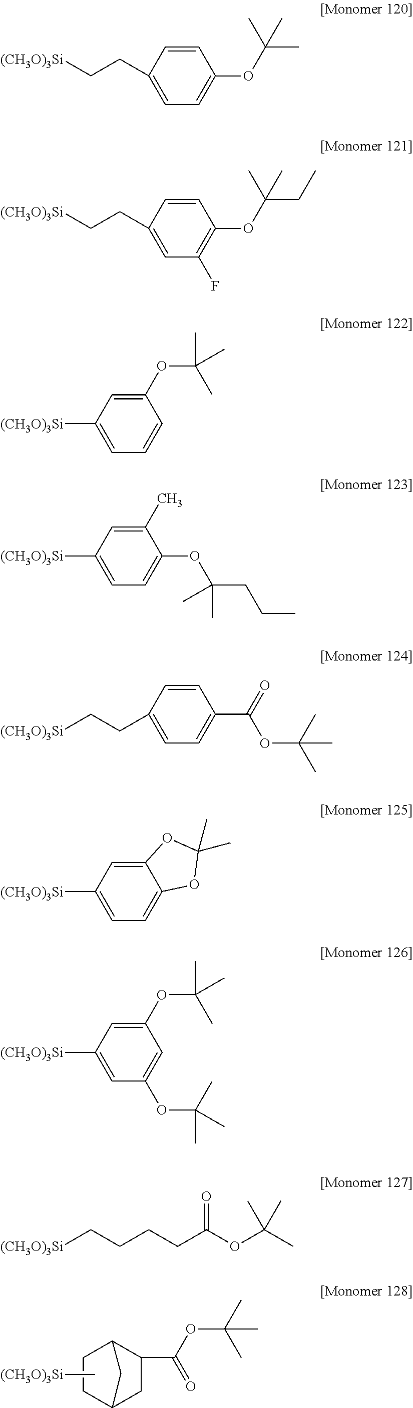

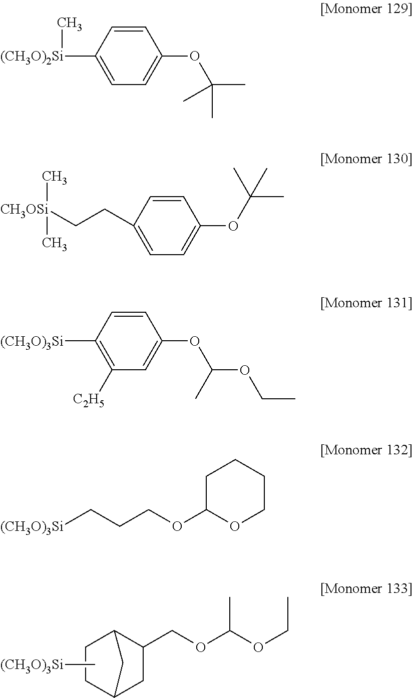

### Synthesis of Component (B)

### Synthesis Example B-1

Mixture of purified water (2.7 g) and isopropyl alcohol (IPA) (50 g) was dropped to mixture of titanium tetraisopropoxide (28.4 g) and IPA (500 g). After completion of dropping, the mixture was agitated for 3 hours. Next, 2-(butylamino)ethanol (11.8 g) was added thereto and agitated for 17 hours. Moreover, 1,2-propanediol (30.4 g) was added thereto and heated to reflux for 2 hours. PGMEA (150 g) was added thereto and was concentrated under reduced pressure to obtain PGMEA solution (130 g) containing nonvolatile matter (19.9 g) as titanium-containing compound (B-1).

### Synthesis Example B-2

Mixture of a purified water (2.7 g) and PGMEA (200 g) was dropped to 1-ethyl-1,2-hexane diol titanate (62.9 g). After completion of dropping, the mixture was agitated at 60° C. for 7 hours to obtain PGMEA solution (176 g) containing nonvolatile matter (28.4 g) as titanium-containing compound (B-2).

### Synthesis Example B-3

Titanium tetra butoxide (34.3 g) was dropped to mixture of 36% hydrochloric acid (3.94 g), purified water (34.9 g) and PGMEA (54.7 g). After completion of dropping, the product was agitated for one hour. Next, a 2-layer separated upper layer was removed, PGMEA (54.7 g) was added to a remaining underlayer to be agitated and the 2-layer separated upper layer was removed. Acetoethyl acetate (20.0 g) was added to the remaining underlayer, and agitated and dissolved to obtain solution (53.4 g). 1,2-propanediol (30.4 g) was added thereto and concentrated under reduced pressure, and PGMEA (150 g) was added thereto to obtain solution (168 g) containing nonvolatile matter (12.9 g) as titanium-containing compound (B-3).

### Synthesis Example B-4

Mixture of purified water (0.6 g) and IPA (13.5 g) was dropped to mixture of titanium tetrabutoxide (13.5 g) and IPA (13.5 g). After completion of dropping, IPA (33.0 g) was added thereto and dropped to mixture of 25% TMAH (32.7 g) and purified water (32.7 g) and IPA (5.4 g). After completion of dropping, the product was agitated for one hour. Next, the product was concentrated under reduced pressure, ethyl acetate (40 g) was added thereto and the product was separated and cleaned with purified water (45 g). PGMEA (75 g) was added thereto and concentrated under reduced pressure to obtain solution (68 g) containing nonvolatile matter (3.5 g) as titanium-containing compound (B-4).

### Synthesis Example B-5

Mixture of titanium tetraisopropoxide (28.4 g) and propylene glycol monomethyl ether (PGEE) (103 g) was heated at 120° C. by a topping apparatus and a distillate was separated to obtain residual (110 g). Mixture of PGEE (24 g) and purified water (2.7 g) was dropped thereto. After completion of dropping, the product was agitated for 3 hours. Next, 2-(butylamino)ethano (111.8 g) was added thereto and agitated for 17 hours. Moreover, 1,2-propanediol (30.4 g) was added thereto and heated to reflux for 2 hours. PGMEA (100 g) was added thereto and concentrated under reduced pressure to obtain solution (126 g) containing nonvolatile matter (21.6 g) as titanium-containing compound (B-5).

### Synthesis Example B-6

Mixed solution of IPA (110 g) and purified water (2.7 g) was dropped to mixture of 75% IPA solution of titanium diisopropoxide-bis-2,4-pentanedionato (48.6 g) and 2,4-pentanedion (10 g). After completion of dropping, the product was agitated for 3 hours. Next, 2-(butylamino)ethanol (11.8 g) was added thereto and agitated for 17 hours. Moreover, 1,2-propanediol (30.4 g) was added thereto and heated to reflux for 2 hours. PGMEA (150 g) was added thereto and concentrated under reduced pressure to obtain solution (141 g) containing a nonvolatile matter (23.1 g) as titanium-containing compound (B-6).

### Example, Comparative Example

The silicon-containing compounds (A−1) to (A-23) as a component (A) and the titanium-containing compounds (B-1) to (B-6) as a component (B) obtained in the above Synthesis Example, a solvent and an additive were mixed according to the ratio shown in Tables 2 and 3, and filtered with a 0.1 μm fluorocarbon resin filter to prepare compositions for forming a titanium-containing resist underlayer film of Example (Sol. 1 to 57) and a composition for forming a resist underlayer film of Comparative Example (Sol. 58).

TABLE 2

| | Component | | | |
|---|---|---|---|---|
| | (A) Silicon- | Component (B) | | |
| | containing | Titanium- | | |
| | compound | containing | | Solvent |
| | (parts | compound | Additive | (parts by |
| No. | by mass) | (parts by mass) | (parts by mass) | mass) |
| Sol. 1 | A-1 (0.1) | B-1 (3.9) | TPSOH (0.04) | PGMEA (145) |
| Sol. 2 | A-1 (0.1) | B-1 (3.9) | TPSHCO₃ | PGMEA (145) |
| | | | (0.04) | |
| Sol. 3 | A-1 (0.1) | B-1 (3.9) | TPSOx (0.04) | PGMEA (145) |
| Sol. 4 | A-1 (0.1) | B-1 (3.9) | TPSTFA (0.04) | PGMEA (145) |
| Sol. 5 | A-1 (0.1) | B-1 (3.9) | TPSOCOPh | PGMEA (145) |
| | | | (0.04) | |
| Sol. 6 | A-1 (0.1) | B-1 (3.9) | TPSH₂PO₄ | PGMEA (145) |
| | | | (0.04) | |
| Sol. 7 | A-1 (0.1) | B-1 (3.9) | QMAMA | PGMEA (145) |
| | | | (0.04) | |
| Sol. 8 | A-1 (0.1) | B-1 (3.9) | QBANO₃ | PGMEA (145) |
| | | | (0.04) | |
| Sol. 9 | A-1 (0.1) | B-1 (3.9) | QMATFA | PGMEA (145) |
| | | | (0.04) | |
| Sol. 10 | A-1 (0.1) | B-1 (3.9) | Ph₂ICl (0.04) | PGMEA (145) |
| Sol. 11 | A-1 (0.1) | B-1 (3.9) | TPSMA (0.04) | PGMEA (145) |
| Sol. 12 | A-2 (0.1) | B-1 (3.9) | TPSMA (0.04) | PGMEA (145) |
| Sol. 13 | A-3 (0.1) | B-1 (3.9) | TPSMA (0.04) | PGMEA (145) |
| Sol. 14 | A-4 (0.1) | B-1 (3.9) | TPSMA (0.04) | PGMEA (145) |
| Sol. 15 | A-5 (0.1) | B-1 (3.9) | TPSMA (0.04) | PGMEA (145) |
| Sol. 16 | A-6 (0.1) | B-1 (3.9) | TPSMA (0.04) | PGMEA (145) |
| Sol. 17 | A-7 (0.1) | B-1 (3.9) | TPSMA (0.04) | PGMEA (145) |
| Sol. 18 | A-8 (0.1) | B-1 (3.9) | TPSMA (0.04) | PGMEA (145) |
| Sol. 19 | A-9 (0.1) | B-1 (3.9) | TPSMA (0.04) | PGMEA (145) |
| Sol. 20 | A-10 (0.1) | B-1 (3.9) | TPSMA (0.04) | PGMEA (145) |
| Sol. 21 | A-11 (0.1) | B-1 (3.9) | TPSMA (0.04) | PGMEA (145) |
| Sol. 22 | A-12 (0.1) | B-1 (3.9) | TPSMA (0.04) | PGMEA (145) |
| Sol. 23 | A-13 (0.1) | B-1 (3.9) | TPSMA (0.04) | PGMEA (145) |
| Sol. 24 | A-14 (0.1) | B-1 (3.9) | TPSMA (0.04) | PGMEA (145) |
| Sol. 25 | A-15 (0.1) | B-1 (3.9) | TPSMA (0.04) | PGMEA (145) |
| Sol. 26 | A-16 (0.1) | B-1 (3.9) | TPSMA (0.04) | PGMEA (145) |
| Sol. 27 | A-17 (0.1) | B-1 (3.9) | TPSMA (0.04) | PGMEA (145) |
| Sol. 28 | A-18 (0.1) | B-1 (3.9) | TPSMA (0.04) | PGMEA (145) |
| Sol. 29 | A-19 (0.1) | B-1 (3.9) | TPSMA (0.04) | PGMEA (145) |
| Sol. 30 | A-20 (0.1) | B-1 (3.9) | TPSMA (0.04) | PGMEA (145) |

TABLE 3

| | Component | | | |
|---|---|---|---|---|
| | (A) Silicon- | Component (B) | | |
| | containing | Titanium- | | |
| | compound | containing | | Solvent |
| | (parts by | compound | Additive | (parts by |
| No. | mass) | (parts by mass) | (parts by mass) | mass) |
| Sol. 31 | A-21 (0.1) | B-1 (3.9) | TPSMA (0.04) | PGMEA (145) |
| Sol. 32 | A-22 (0.1) | B-1 (3.9) | TPSMA (0.04) | PGMEA (145) |
| Sol. 33 | A-23 (0.1) | B-1 (3.9) | TPSMA (0.04) | PGMEA (145) |
| Sol. 34 | A-3 (0.1) | B-2 (3.9) | TPSMA (0.04) | PGMEA (145) |
| Sol. 35 | A-3 (0.1) | B-3 (3.9) | TPSMA (0.04) | PGMEA (120) |
| Sol. 36 | A-3 (0.1) | B-4 (3.9) | TPSMA (0.04) | PGMEA (95) |
| Sol. 37 | A-3 (0.1) | B-5 (3.9) | TPSMA (0.04) | PGMEA (150) |
| Sol. 38 | A-3 (0.1) | B-6 (3.9) | TPSMA (0.04) | PGMEA (145) |
| Sol. 39 | A-4 (0.1) | B-2 (3.9) | TPSMA (0.04) | PGMEA (145) |
| Sol. 40 | A-4 (0.1) | B-3 (3.9) | TPSMA (0.04) | PGMEA (120) |
| Sol. 41 | A-4 (0.1) | B-4 (3.9) | TPSMA (0.04) | PGMEA (95) |
| Sol. 42 | A-4 (0.1) | B-5 (3.9) | TPSMA (0.04) | PGMEA (150) |
| Sol. 43 | A-4 (0.1) | B-6 (3.9) | TPSMA (0.04) | PGMEA (145) |
| Sol. 44 | A-12 (0.1) | B-2 (3.9) | TPSMA (0.04) | PGMEA (145) |
| Sol. 45 | A-12 (0.1) | B-3 (3.9) | TPSMA (0.04) | PGMEA (120) |
| Sol. 46 | A-12 (0.1) | B-4 (3.9) | TPSMA (0.04) | PGMEA (95) |
| Sol. 47 | A-12 (0.1) | B-5 (3.9) | TPSMA (0.04) | PGMEA (150) |
| Sol. 48 | A-12 (0.1) | B-6 (3.9) | TPSMA (0.04) | PGMEA (145) |
| Sol. 49 | A-23 (0.1) | B-2 (3.9) | TPSMA (0.04) | PGMEA (145) |
| Sol. 50 | A-23 (0.1) | B-3 (3.9) | TPSMA (0.04) | PGMEA (120) |
| Sol. 51 | A-23 (0.1) | B-4 (3.9) | TPSMA (0.04) | PGMEA (95) |
| Sol. 52 | A-23 (0.1) | B-5 (3.9) | TPSMA (0.04) | PGMEA (150) |
| Sol. 53 | A-23 (0.1) | B-6 (3.9) | TPSMA (0.04) | PGMEA (145) |
| Sol. 54 | A-3 (0.2) | B-2 (3.8) | TPSMA (0.04) | PGMEA (145) |
| Sol. 55 | A-3 (0.4) | B-2 (3.6) | TPSMA (0.04) | PGMEA (145) |
| Sol. 56 | A-3 (0.6) | B-2 (3.4) | TPSMA (0.04) | PGMEA (145) |
| Sol. 57 | A-3 (0.8) | B-2 (3.2) | TPSMA (0.04) | PGMEA (145) |
| Sol. 58 | A-3 (4.0) | — | TPSMA (0.04) | PGMEA (145) |

TPSOH: triphenylsulfonium hydroxide
TPSHCO₃: mono(triphenylsulfonium) carbonate
TPSOX: mono(triphenylsulfonium) oxalate
TPSTFA: triphenylsulfonium trifluoroacetate
TPSOCOPH: triphenylsulfonium benzoate
TPSH₂PO₄: mono(triphenylsulfonium) phosphate
TPSMA: mono(triphenylsulfonium) malate
QMAMA: mono(tetramethylammonium) malate
QMATFA: tetramethylammonium trifluoroacetate
QBANO₃: tetrabutylammonium nitrate
PH₂ICL: diphenyleneiodonium chloride

### Coating Film Etching Test

The compositions for forming a resist underlayer film (Sol. 1 to 58) were applied on a silicon wafer by spin-coating and heated at 240° C. for 60 seconds to produce a 35 nm resist underlayer film (Films 1 to 58). The resist underlayer films were each subjected to dry etching on the following conditions (1) and (2). Tables 4 and 5 show the results.

### (1) Etching Condition by Using CHF₃/CF₄ Gas

Apparatus: dry etching apparatus Telius SP (Product from Tokyo Electron Limited.)

Etching condition (1):

| Chamber pressure | 10 | Pa |
|---|---|---|
| Upper/Lower RF power | 500 W/300 W | |
| CHF₃ gas flow rate | 50 | ml/min |
| CF₄ gas flow rate | 150 | ml/min |
| AR gas flow rate | 100 | ml/min |
| Processing time | 10 | sec |

(2) Etching condition by using CO₂/N₂ gas
Apparatus: dry etching apparatus Telius SP (Product from Tokyo Electron Limited.)

Etching condition (2):

| Chamber pressure | 2 | Pa |
|---|---|---|
| Upper/Lower RF power | 1000 W/300 W | |
| CO₂ gas flow rate | 300 | ml/min |
| N₂ gas flow rate | 100 | ml/min |
| Processing time | 15 | sec |

TABLE 4

| Composition for | Titanium- | CHF₃/CF₄ gas | CO₂/N₂ gas |
|---|---|---|---|
| forming titanium- | containing | dry etching | dry etching |
| containing resist | resist | rate | rate |
| underlayer film | underlayer film | (nm/min) | (nm/min) |
| Sol. 1 | Film 1 | 11 | 3 |
| Sol. 2 | Film 2 | 11 | 4 |
| Sol. 3 | Film 3 | 11 | 3 |
| Sol. 4 | Film 4 | 11 | 3 |
| Sol. 5 | Film 5 | 12 | 3 |
| Sol. 6 | Film 6 | 11 | 3 |
| Sol. 7 | Film 7 | 12 | 3 |
| Sol. 8 | Film 8 | 11 | 3 |
| Sol. 9 | Film 9 | 10 | 4 |
| Sol. 10 | Film 10 | 11 | 4 |
| Sol. 11 | Film 11 | 12 | 4 |
| Sol. 12 | Film 12 | 11 | 4 |
| Sol. 13 | Film 13 | 12 | 3 |
| Sol. 14 | Film 14 | 11 | 3 |
| Sol. 15 | Film 15 | 12 | 3 |
| Sol. 16 | Film 16 | 12 | 3 |
| Sol. 17 | Film 17 | 12 | 4 |
| Sol. 18 | Film 18 | 11 | 4 |
| Sol. 19 | Film 19 | 11 | 3 |
| Sol. 20 | Film 20 | 12 | 4 |
| Sol. 21 | Film 21 | 12 | 4 |
| Sol. 22 | Film 22 | 12 | 4 |
| Sol. 23 | Film 23 | 11 | 3 |
| Sol. 24 | Film 24 | 11 | 3 |
| Sol. 25 | Film 25 | 12 | 3 |
| Sol. 26 | Film 26 | 11 | 4 |
| Sol. 27 | Film 27 | 11 | 4 |
| Sol. 28 | Film 28 | 11 | 3 |
| Sol. 29 | Film 29 | 11 | 4 |
| Sol. 30 | Film 30 | 11 | 4 |

TABLE 5

| Composition for | Titanium- | CHF₃/CF₄ gas | CO₂/N₂ gas |
|---|---|---|---|
| forming titanium- | containing | dry etching | dry etching |
| containing resist | resist | rate | rate |
| underlayer film | underlayer film | (nm/min) | (nm/min) |
| Sol. 31 | Film 31 | 10 | 4 |
| Sol. 32 | Film 32 | 12 | 4 |
| Sol. 33 | Film 33 | 11 | 4 |
| Sol. 34 | Film 34 | 11 | 3 |
| Sol. 35 | Film 35 | 12 | 3 |
| Sol. 36 | Film 36 | 11 | 4 |
| Sol. 37 | Film 37 | 10 | 4 |
| Sol. 38 | Film 38 | 11 | 4 |
| Sol. 39 | Film 39 | 10 | 4 |
| Sol. 40 | Film 40 | 11 | 3 |
| Sol. 41 | Film 41 | 11 | 3 |
| Sol. 42 | Film 42 | 11 | 3 |
| Sol. 43 | Film 43 | 10 | 3 |
| Sol. 44 | Film 44 | 10 | 4 |
| Sol. 45 | Film 45 | 11 | 3 |
| Sol. 46 | Film 46 | 11 | 3 |
| Sol. 47 | Film 47 | 11 | 3 |
| Sol. 48 | Film 48 | 10 | 4 |
| Sol. 49 | Film 49 | 11 | 4 |
| Sol. 50 | Film 50 | 12 | 4 |
| Sol. 51 | Film 51 | 11 | 4 |
| Sol. 52 | Film 52 | 11 | 3 |
| Sol. 53 | Film 53 | 11 | 3 |
| Sol. 54 | Film 54 | 12 | 4 |
| Sol. 55 | Film 55 | 13 | 4 |
| Sol. 56 | Film 56 | 14 | 4 |
| Sol. 57 | Film 57 | 20 | 3 |
| Sol. 58 | Film 58 | 60 | 4 |

In every underlayer film, there was no difference in dry etching rate observed using CO₂/N₂ gas. When CF gas used in dry etching of a silicon-containing film was used, resist underlayer films (Films 1 to 57) containing a titanium-containing compound exhibited lower dry etching rate and etching resistance. In particular, if the rate of silicon-containing compound relative to the total of titanium-containing compound and silicon-containing compound is 15% by mass or less (Films 1 to 56), etching resistance was found favorable. However, a resist underlayer film (Film 58) containing no titanium-containing compound obviously demonstrated higher dry etching rate.

### Positive Development Patterning Test

A 200 nm spin-on carbon film ODL-50 (Product from Shin-Etsu Chemical Co., Ltd.: carbon content; 80% by mass) was formed on a silicon wafer. The compositions for forming titanium-containing resist underlayer films (Sol. 11 to 38) were applied thereon and heated at 240° C. for 60 seconds to prepare titanium-containing resist underlayer films with film thickness of 35 nm (Films 11 to 38). Subsequently, ArF resist solution for positive development (PR-1) described in Table 6 was applied on the titanium-containing resist underlayer films and baked at 110° C. for 60 seconds to form 100 nm photoresist layers. Immersion top coat (TC-1) described in Table 7 was further applied on the photoresist films and baked at 90° C. for 60 seconds to form 50 nm top coats. Subsequently, the products were subjected to exposure with an ArF-immersion exposure apparatus (Product from Nikon Corporation; NSR-S610C, NA-1.30, σ=0.98/0.65, 35-degree dipole polarized light illumination, 6%-attenuated phase shift mask), baked at 100° C. for 60 seconds (PEB), and developed with a 2.38% by mass tetramethylammonium hydroxide (TMAH) aqueous solution for 30 seconds to obtain 50 nm 1:1 positive line-and-space pattern. The pattern collapse was measured with an electronic microscope (Product from Hitachi High-Technologies Corporation (CG4000) and the cross section was observed with an electronic microscope (Product from Hitachi Ltd. (S-9380)). Table 8 shows the results.

TABLE 6

| | Polymer | Acid generator | Base | Solvent |
|---|---|---|---|---|
| | (parts by | (parts by | (parts by | (parts by |
| No. | mass) | mass) | mass) | mass) |
| PR-1 | P1 | PAG1 | Q1 | PGMEA |
| | (100) | (7.0) | (1.0) | (2500) |

TABLE 7

| | Polymer | Solvent |
|---|---|---|
| | (parts by mass) | (parts by mass) |
| TC-1 | P2(100) | diisoamyl ether (2700) |
| | | 2-methyl-1-butanol (270) |

ArF resist polymer: P1

Molecular weight (Mw)=7,800

Degree of dispersion (Mw/Mn)=1.78

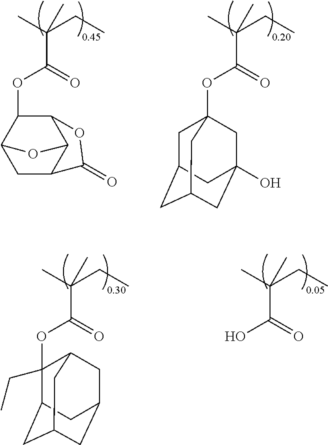

Acid generator: PAG1

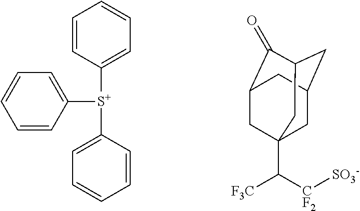

### Base: Q1

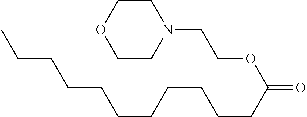 [SMILES: CCCCCCCCCCCC(=O)OCCN1CCOCC1]

Top coat polymer: P2

Molecular weight (Mw)=8,800

Degree of dispersion (Mw/Mn)=1.69

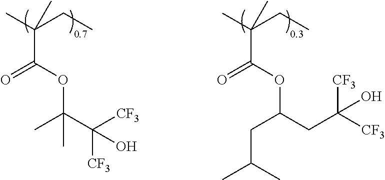

TABLE 8

| | Titanium- | | |
|---|---|---|---|
| | containing | | |
| | resist | | |
| | underlayer | Pattern cross- | Pattern |
| Example | film | sectional shape | collapse |
| Example 1-1 | Film 11 | Vertical shape | None |
| Example 1-2 | Film 12 | Vertical shape | None |
| Example 1-3 | Film 13 | Vertical shape | None |
| Example 1-4 | Film 14 | Vertical shape | None |
| Example 1-5 | Film 15 | Vertical shape | None |
| Example 1-6 | Film 16 | Vertical shape | None |
| Example 1-7 | Film 17 | Vertical shape | None |
| Example 1-8 | Film 18 | Vertical shape | None |
| Example 1-9 | Film 19 | Vertical shape | None |
| Example 1-10 | Film 20 | Vertical shape | None |
| Example 1-11 | Film 21 | Vertical shape | None |
| Example 1-12 | Film 22 | Vertical shape | None |
| Example 1-13 | Film 23 | Vertical shape | None |
| Example 1-14 | Film 24 | Vertical shape | None |
| Example 1-15 | Film 25 | Vertical shape | None |
| Example 1-16 | Film 26 | Vertical shape | None |
| Example 1-17 | Film 27 | Vertical shape | None |
| Example 1-18 | Film 28 | Vertical shape | None |
| Example 1-19 | Film 29 | Vertical shape | None |
| Example 1-20 | Film 30 | Vertical shape | None |
| Example 1-21 | Film 31 | Vertical shape | None |
| Example 1-22 | Film 32 | Vertical shape | None |
| Example 1-23 | Film 33 | Vertical shape | None |
| Example 1-24 | Film 34 | Vertical shape | None |
| Example 1-25 | Film 35 | Vertical shape | None |
| Example 1-26 | Film 36 | Vertical shape | None |
| Example 1-27 | Film 37 | Vertical shape | None |
| Example 1-28 | Film 38 | Vertical shape | None |

In positive development, as shown in Table 8, a pattern, having no pattern collapse with a line width of up to 50 nm of a cross-sectional shape in vertical direction, was obtained.

### Negative Development Patterning Test

A 200 nm spin-on carbon film ODL-50 (Product from Shin-Etsu Chemical Co., Ltd.: carbon content; 80% by mass) was formed on a silicon wafer. The compositions for forming titanium-containing resist underlayer films (Sol. 11 to 38) were applied thereon and heated at 240° C. for 60 seconds to prepare titanium-containing resist underlayer films with a film thickness of 35 nm (Films 11 to 38). Subsequently, ArF resist solution for negative development (PR-2) described in Table 9 was applied on the titanium-containing resist underlayer films and baked at 110° C. for 60 seconds to form 100 nm photoresist layers. Immersion top coat (TC-1) described in Table 7 was further applied on the photoresist films and baked at 90° C. for 60 seconds to form 50 nm top coats. Subsequently, the products were subjected to exposure with ArF-immersion exposure apparatus (Product from Nikon Corporation; NSR-S610C, NA=1.30, σ=0.98/0.65, 35-degree dipole polarized light illumination, 6%-attenuated phase shift mask), baked at 100° C. for 60 seconds (PEB), and rotated at 30 rpm to discharge butyl acetate from a development nozzle as developer for 3 seconds. Thereafter, the rotation was halted, paddle development was carried out for 27 seconds, spin-dried with diisoamyl ether after rinsing, baked at 100° C. for 20 seconds and rinsing solvent was evaporated to obtain a 50 nm 1:1 negative line-and-space pattern. The pattern collapse was measured with an electronic microscope (Product from Hitachi High-Technologies Corporation (CG4000) and the cross section was observed with an electronic microscope (Product from Hitachi Ltd. (S-9380)). Table 10 shows the results.

TABLE 9

| | Polymer | Acid generator | Base | Solvent |
|---|---|---|---|---|
| | (parts by | (parts by | (parts by | (parts by |
| No. | mass) | mass) | mass) | mass) |
| PR-2 | P3 | PAG1 | Q1 | PGMEA |
| | (100) | (7.0) | (1.0) | (2500) |

ArF resist polymer: 23

Molecular weight (Mw)=8,600

Degree of dispersion (Mw/Mn)=1.88

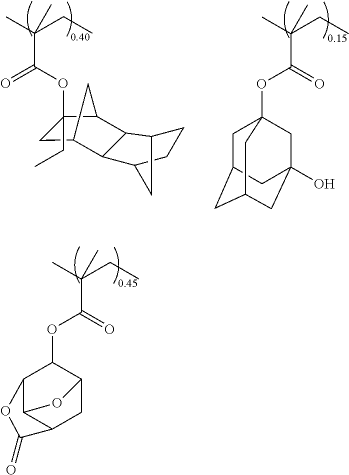

TABLE 10

| | Titanium- | | |
|---|---|---|---|
| | containing | | |
| | resist | | |
| | underlayer | Pattern cross- | Pattern |
| Example | film | sectional shape | collapse |
| Example 2-1 | Film 11 | Vertical shape | None |
| Example 2-2 | Film 12 | Vertical shape | None |
| Example 2-3 | Film 13 | Vertical shape | None |
| Example 2-4 | Film 14 | Vertical shape | None |
| Example 2-5 | Film 15 | Vertical shape | None |
| Example 2-6 | Film 16 | Vertical shape | None |
| Example 2-7 | Film 17 | Vertical shape | None |
| Example 2-8 | Film 18 | Vertical shape | None |
| Example 2-9 | Film 19 | Vertical shape | None |
| Example 2-10 | Film 20 | Vertical shape | None |
| Example 2-11 | Film 21 | Vertical shape | None |
| Example 2-12 | Film 22 | Vertical shape | None |
| Example 2-13 | Film 23 | Vertical shape | None |
| Example 2-14 | Film 24 | Vertical shape | None |
| Example 2-15 | Film 25 | Vertical shape | None |
| Example 2-16 | Film 26 | Vertical shape | None |
| Example 2-17 | Film 27 | Vertical shape | None |
| Example 2-18 | Film 28 | Vertical shape | None |
| Example 2-19 | Film 29 | Vertical shape | None |
| Example 2-20 | Film 30 | Vertical shape | None |
| Example 2-21 | Film 31 | Vertical shape | None |
| Example 2-22 | Film 32 | Vertical shape | None |
| Example 2-23 | Film 33 | Vertical shape | None |
| Example 2-24 | Film 34 | Vertical shape | None |
| Example 2-25 | Film 35 | Vertical shape | None |
| Example 2-26 | Film 36 | Vertical shape | None |
| Example 2-27 | Film 37 | Vertical shape | None |
| Example 2-28 | Film 38 | Vertical shape | None |

In negative development, as shown in Table 10, a pattern, having no pattern collapse with a line width of up to 50 nm of a cross-sectional shape in vertical direction, was obtained.

From the above results, the composition for forming a titanium-containing resist underlayer film of the present invention can form resist underlayer film having favorable etching selectivity relative to organic film and silicon-containing film and having favorable pattern adhesiveness in both positive patterning and negative patterning, and can obtain fine pattern by patterning using the same.

It must be stated here that the present invention is not restricted to the embodiments shown by Examples. The embodiments shown by Examples are merely examples so that any embodiments composed of substantially the same technical concept as disclosed in the claims of the present invention and expressing a similar effect are included in the technical scope of the present invention.

What is claimed is:

1. A composition for forming a titanium-containing resist underlayer film comprising:
as a component (A), a silicon-containing compound obtained by hydrolysis and/or condensation of one or more kinds of silicon compounds shown by the following general formula (A-I),
R^{1A}ₐ₁R^{2A}ₐ₂R^{3A}ₐ₃Si(OR^{0A})₍₄₋ₐ₁₋ₐ₂₋ₐ₃₎ (A-I)
wherein, R^{OA} represents a hydrocarbon group having 1 to 6 carbon atoms; R^{1A}, R^{2A} and R^{3A} represent a hydrogen atom or a monovalent organic group having 1 to 30 carbon atoms; and a1, a2 and a3 represent 0 or 1 and satisfy 1≦a1+a2+a3≦3, and
as a component (B), a titanium-containing compound obtained by hydrolysis and/or condensation of one or more kinds of hydrolysable titanium compounds shown by the following general formula (B-I),
Ti(OR^{0B})₄ (B-I)
wherein, R^{0B} represents an organic group having 1 to 10 carbon atoms.

2. The composition for forming a titanium-containing resist underlayer film according to claim 1, wherein the component (A) contains a silicon-containing compound obtained by hydrolysis and/or condensation of one or more kinds of silicon compounds shown by the general formula (A-I) and one or more kinds of hydrolysable metal compounds shown by the following general formula (A-II),
L(OR^{4A})ₐ₄(OR^{5A})ₐ₅(O)ₐ₆ (A-II)
wherein, R^{4A} and R^{5A} represent an organic group having 1 to 30 carbon atoms; a4, a5 and a6 represent an integer of 0 or more and a4+a5+2×a6 is the same number as the number determined by valency of L; and L is an element belonging to groups of III, IV, or V in a periodic table except for carbon.

3. The composition for forming a titanium-containing resist underlayer film according to claim 2, wherein L of the general formula (A-II) is any of boron, silicon, aluminum, gallium, yttrium, germanium, titanium, zirconium, hafnium, bismuth, tin, phosphorous, vanadium, arsenic, antimony, niobium, and tantalum.

4. The composition for forming a titanium-containing resist underlayer film according to claim 1, wherein any one or more of R^{1A}, R^{2A} and R^{3A} is an organic group containing a hydroxyl group or a carboxyl group, the groups being substituted with an acid-labile group.

5. The composition for forming a titanium-containing resist underlayer film according to claim 2, wherein any one or more of R^{1A}, R^{2A} and R^{3A} is an organic group containing a hydroxyl group or a carboxyl group, the groups being substituted with an acid-labile group.

6. The composition for forming a titanium-containing resist underlayer film according to claim 3, wherein any one or more of R^{1A}, R^{2A} and R^{3A} is an organic group containing a hydroxyl group or a carboxyl group, the groups being substituted with an acid-labile group.

7. A patterning process, the patterning process to form a pattern on a body to be processed, wherein an organic underlayer film is formed on a body to be processed by using an application-type composition for the organic underlayer film, on this organic underlayer film is formed a titanium-containing resist underlayer film by using the composition for forming the titanium-containing resist underlayer film according to claim 1, on this titanium-containing resist underlayer film is formed a photoresist film by using a chemically amplified resist composition, the photoresist film is exposed to a high energy beam after heat treatment, a positive pattern is formed by dissolving an exposed area of the photoresist film by using an alkaline developer, pattern transfer is made onto the titanium-containing resist underlayer film by using the photoresist film having the positive pattern as a mask, pattern transfer is made onto the organic underlayer film by using the titanium-containing resist underlayer film having the transferred pattern as a mask, and then pattern transfer is made onto the body to be processed by using the organic underlayer film having the transferred pattern as a mask.

8. A patterning process, the patterning process to form a pattern on a body to be processed, wherein an organic hard mask mainly comprising carbon is formed on a body to be processed by a CVD method, on this organic hard mask is formed a titanium-containing resist underlayer film by using the composition for forming the titanium-containing resist underlayer film according to claim 1, on this titanium-containing resist underlayer film is formed a photoresist film by using a chemically amplified resist composition, the photoresist film is exposed to a high energy beam after heat treatment, a positive pattern is formed by dissolving an exposed area of the photoresist film by using an alkaline developer, pattern transfer is made onto the titanium-containing resist underlayer film by using the photoresist film having the positive pattern as a mask, pattern transfer is made onto the organic hard mask by using the titanium-containing resist underlayer film having the transferred pattern as a mask, and then pattern transfer is made onto the body to be processed by using the organic hard mask having the transferred pattern as a mask.

9. A patterning process, the patterning process to form a pattern on a body to be processed, wherein an organic underlayer film is formed on a body to be processed by using an application-type composition for the organic underlayer film, on this organic underlayer film is formed a titanium-containing resist underlayer film by using the composition for forming the titanium-containing resist underlayer film according to claim 1, on this titanium-containing resist underlayer film is formed a photoresist film by using a chemically amplified resist composition, the photoresist film is exposed to a high energy beam after heat treatment, a negative pattern is formed by dissolving an unexposed area of the photoresist film by using an organic solvent developer, pattern transfer is made onto the titanium-containing resist underlayer film by using the photoresist film having the negative pattern as a mask, pattern transfer is made onto the organic underlayer film by using the titanium-containing resist underlayer film having the transferred pattern as a mask, and then pattern transfer is made onto the body to be processed by using the organic underlayer film having the transferred pattern as a mask.

10. A patterning process, the patterning process to form a pattern on a body to be processed, wherein an organic hard mask mainly comprising carbon is formed on a body to be processed by a CVD method, on this organic hard mask is formed a titanium-containing resist underlayer film by using the composition for forming the titanium-containing resist underlayer film according to claim 1, on this titanium-containing resist underlayer film is formed a photoresist film by using a chemically amplified resist composition, the photoresist film is exposed to a high energy beam after heat treatment, a negative pattern is formed by dissolving an unexposed area of the photoresist film by using an organic solvent developer, pattern transfer is made onto the titanium-containing resist underlayer film by using the photoresist film having the negative pattern as a mask, pattern transfer is made onto the organic hard mask by using the titanium-containing resist underlayer film having the transferred pattern as a mask, and then pattern transfer is made onto the body to be processed by using the organic hard mask having the transferred pattern as a mask.

11. The patterning process according to claim 7, wherein the body to be processed is a semiconductor substrate coated, as a layer to be processed, with any of a metal film, a metal carbide film, a metal oxide film, a metal nitride film, a metal oxycarbide film, and a metal oxynitride film.

12. The patterning process according to claim 8, wherein the body to be processed is a semiconductor substrate coated, as a layer to be processed, with any of a metal film, a metal carbide film, a metal oxide film, a metal nitride film, a metal oxycarbide film, and a metal oxynitride film.

13. The patterning process according to claim 9, wherein the body to be processed is a semiconductor substrate coated, as a layer to be processed, with any of a metal film, a metal carbide film, a metal oxide film, a metal nitride film, a metal oxycarbide film, and a metal oxynitride film.

14. The patterning process according to claim 10, wherein the body to be processed is a semiconductor substrate coated, as a layer to be processed, with any of a metal film, a metal carbide film, a metal oxide film, a metal nitride film, a metal oxycarbide film, and a metal oxynitride film.

15. The patterning process according to claim 11, wherein the metal that constitutes the body to be processed is silicon, titanium, tungsten, hafnium, zirconium, chromium, germanium, copper, aluminum, indium, gallium, arsenic, palladium, iron, tantalum, iridium, molybdenum or an alloy of these metals.

16. The patterning process according to claim 12, wherein the metal that constitutes the body to be processed is silicon, titanium, tungsten, hafnium, zirconium, chromium, germanium, copper, aluminum, indium, gallium, arsenic, palladium, iron, tantalum, iridium, molybdenum or an alloy of these metals.

17. The patterning process according to claim 13, wherein the metal that constitutes the body to be processed is silicon, titanium, tungsten, hafnium, zirconium, chromium, germanium, copper, aluminum, indium, gallium, arsenic, palladium, iron, tantalum, iridium, molybdenum or an alloy of these metals.

18. The patterning process according to claim 14, wherein the metal that constitutes the body to be processed is silicon, titanium, tungsten, hafnium, zirconium, chromium, germanium, copper, aluminum, indium, gallium, arsenic, palladium, iron, tantalum, iridium, molybdenum or an alloy of these metals.

19. The patterning process according to claim 7, wherein the photoresist film is exposed by the method of photolithography with the wavelength of 300 nm or less or an EUV beam or by the method of a direct drawing with an electron beam.

20. The patterning process according to claim 8, wherein the photoresist film is exposed by the method of photolithography with the wavelength of 300 nm or less or an EUV beam or by the method of a direct drawing with an electron beam.

21. The patterning process according to claim 9, wherein the photoresist film is exposed by the method of photolithography with the wavelength of 300 nm or less or an EUV beam or by the method of a direct drawing with an electron beam.

22. The patterning process according to claim 10, wherein the photoresist film is exposed by the method of photolithography with the wavelength of 300 nm or less or an EUV beam or by the method of a direct drawing with an electron beam.
